(19) United States
(12) Patent Application Publication
(10) Pub. No.: US 2025/0105140 A1
(43) Pub. Date: Mar. 27, 2025

(54) SEMICONDUCTOR DEVICE INCLUDING INTERCONNECT STRUCTURE AND METHOD FOR MANUFACTURING THE SAME

(71) Applicant: Taiwan Semiconductor Manufacturing Company, Ltd., Hsinchu (TW)

(72) Inventors: Shih-Kang FU, Hsinchu (TW); Hsien-Chang WU, Hsinchu (TW); Ming-Han LEE, Hsinchu (TW)

(73) Assignee: Taiwan Semiconductor Manufacturing Company, Ltd., Hsinchu (TW)

(21) Appl. No.: 18/474,613

(22) Filed: Sep. 26, 2023

(51) Int. Cl. H01L 23/522; H01L 21/768

(52) U.S. Cl. CPC H01L 23/5226; H01L 21/7682; H01L 21/76829; H01L 21/7684; H01L 21/7685; H01L 21/76867

(57) ABSTRACT

A method for manufacturing a semiconductor device includes: forming a plurality of sacrificial stack portions on a semiconductor substrate, the sacrificial stack portions being spaced apart from each other; forming a metal material layer to cover the sacrificial stack portions, the metal material layer including a first metal and a second metal different from the first metal, the first metal having a reduction potential lower than that of the second metal; and annealing the metal material layer to form a self-forming barrier layer conformally covering the sacrificial stack portions, the self-forming barrier layer including a metal oxide, a metal silicide, or a combination thereof formed from the first metal by annealing.

### BACKGROUND

The integration density of various electronic components, such as transistors, diodes, resistors, capacitors, etc., is being improved continuously in the semiconductor industry by continual reduction in minimum feature sizes. As the feature sizes are decreased, the distance between metal features is continually reduced. As the distance between the metal features reduces, resulting resistance and parasitic capacitance increase, leading to larger resistance-capacitance (RC) time delay for integrated chips.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are flow diagrams illustrating a method for manufacturing a semiconductor device in accordance with some embodiments.

FIGS. 2 to 26 illustrate schematic views of some intermediate stages of the method depicted in FIGS. 1A and 1B in accordance with some embodiments.

FIGS. 27A and 27B are flow diagrams illustrating a method for manufacturing a semiconductor device in accordance with some embodiments.

FIGS. 28 to 55 illustrate schematic views of some intermediate stages of the method depicted in FIGS. 27A and 27B in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” ““upper,” “lower,” “below,” “over,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The integration density of various electronic components, such as transistors, diodes, resistors, capacitors, etc., is being improved continuously in the semiconductor industry by continual reduction in minimum feature sizes. As the feature sizes are decreased, the distance between metal features is continually reduced. As the distance between the metal features reduces, resulting resistance and parasitic capacitance increase, leading to larger resistance-capacitance (RC) time delay for integrated chips. The present disclosure is directed to a method for manufacturing a semiconductor device with reduced capacitance and resistivity.

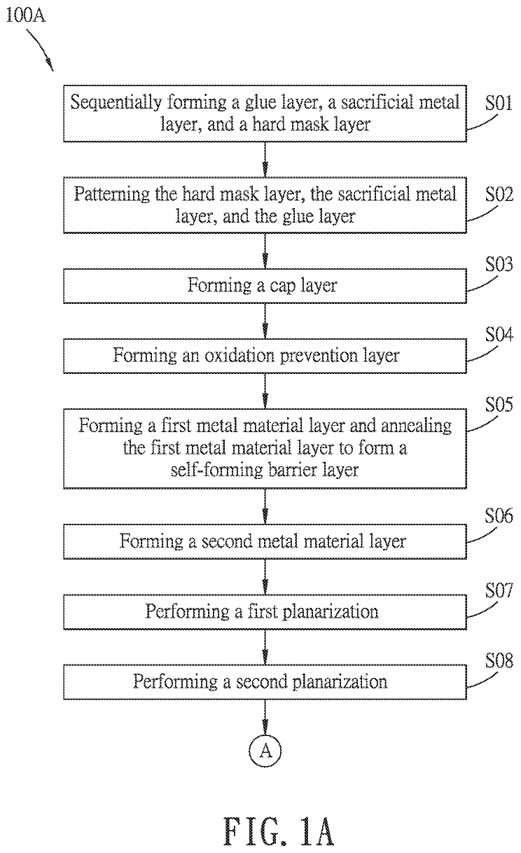

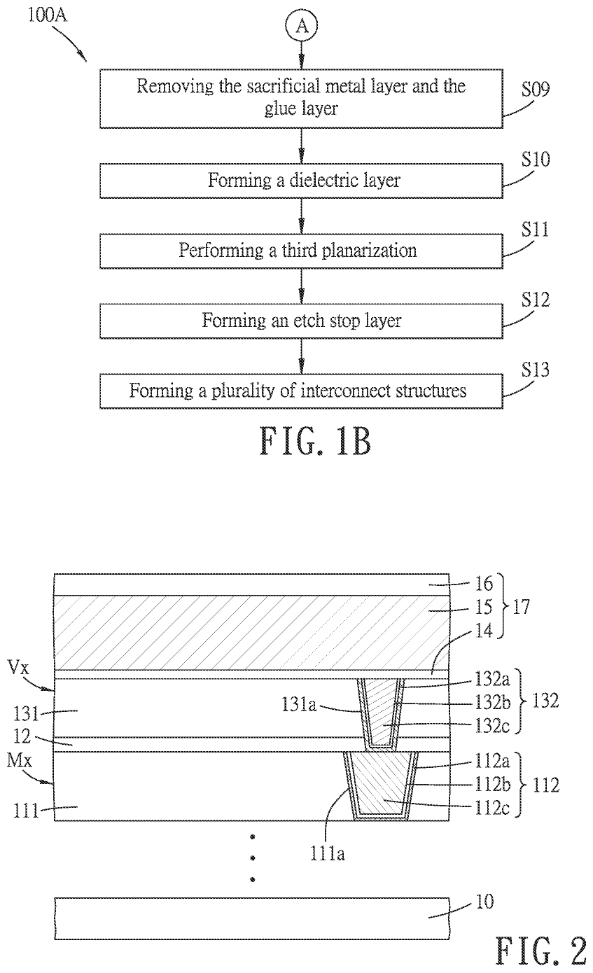

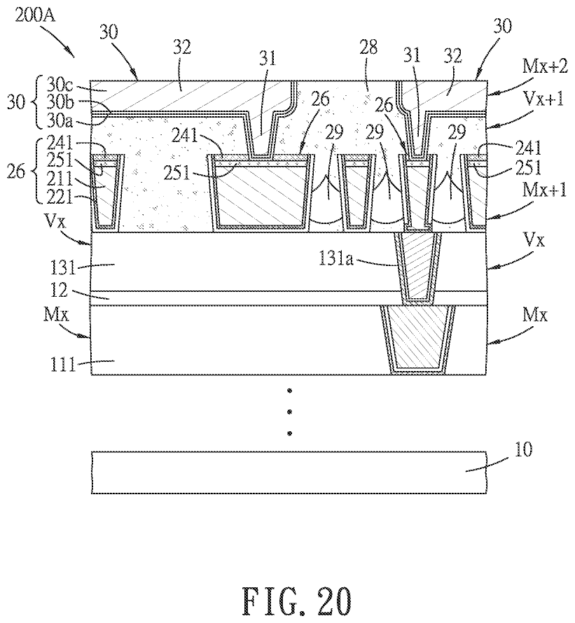

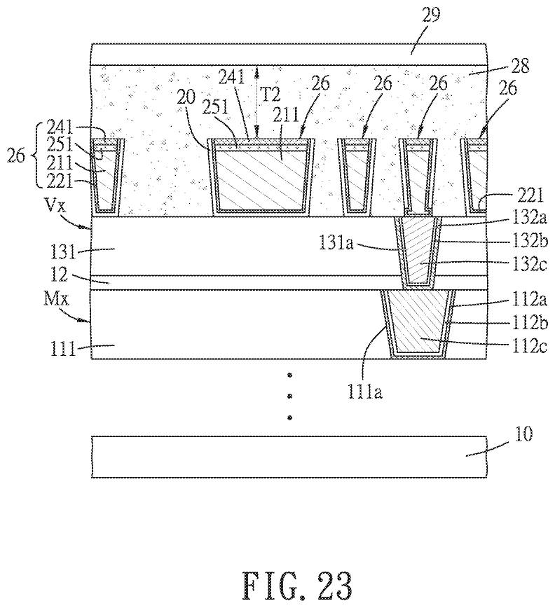

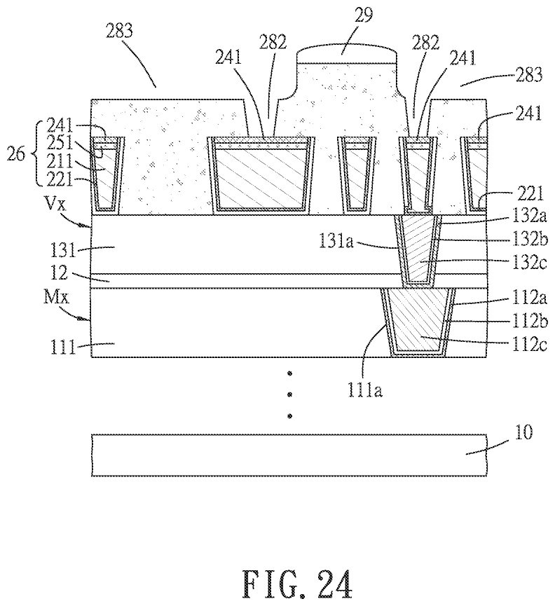

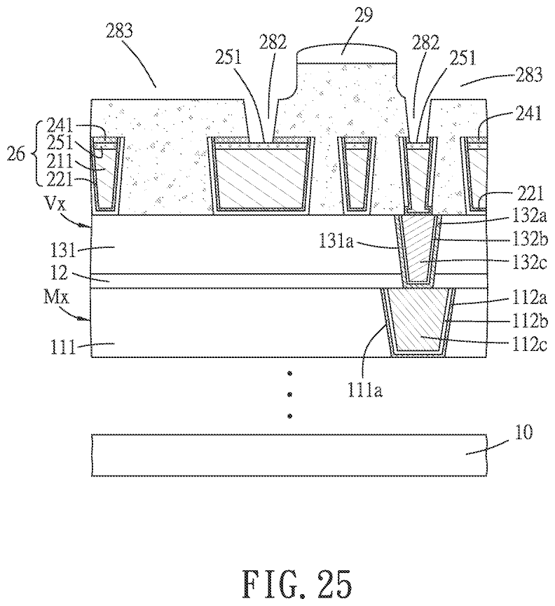

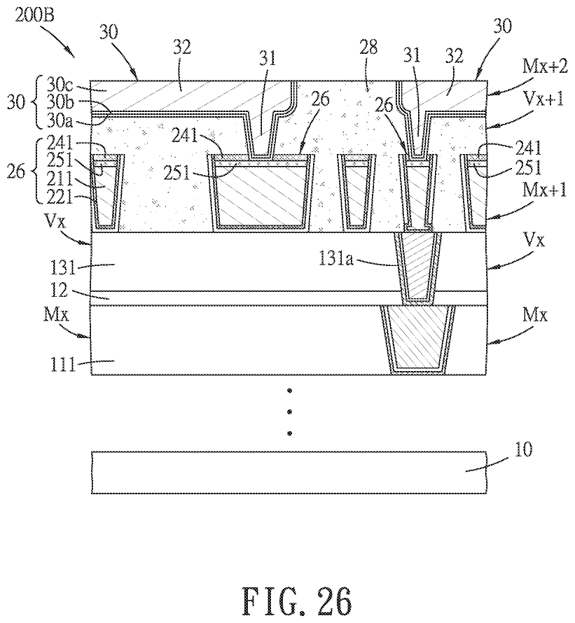

FIGS. 1A and 1B are flow diagram illustrating a method 100A for manufacturing a semiconductor device (for example, a semiconductor device 200A shown in FIG. 20 and a semiconductor device 200B shown in FIG. 26) in accordance with some embodiments. FIGS. 2 to 26 illustrate schematic views of some intermediate stages of the method 100A in accordance with some embodiments. Some portions may be omitted in FIGS. 2 to 26 for the sake of brevity. Additional steps can be provided before, after or during the method 100A, and some of the steps described herein may be replaced by other steps or be eliminated. Similarly, further additional features may be present in the semiconductor device 200A and the semiconductor device 200B, and/or features present may be replaced or eliminated in additional embodiments.

Referring to FIG. 1A and the example illustrated in FIG. 2, the method 100A begins at step S01, where a glue layer 14, a sacrificial metal layer 15, and a hard mask layer 16 are formed sequentially. In some embodiments, the glue layer 14, the sacrificial metal layer 15, and the hard mask layer 16 are formed sequentially on a via layer (Vx) disposed on a metal layer (Mx). The metal layer (Mx) is disposed on a semiconductor substrate 10 and is separated from the via layer (Vx) by an etch stop layer 12. The glue layer 14, the sacrificial metal layer 15, and the hard mask layer 16 are collectively referred to as a sacrificial stack 17.

In some embodiments, the semiconductor substrate 10 may include, for example, but not limited to, an elemental semiconductor or a compound semiconductor. In some embodiments, the elemental semiconductor includes a single species of atoms, such as silicon (Si) or germanium (Ge) in column XIV of the periodic table, and may be in a crystal form, a polycrystalline form, or an amorphous form. Other suitable elemental semiconductor materials are within the contemplated scope of the present disclosure. In some embodiments, the compound semiconductor includes two or more elements, and examples thereof may include, but not limited to, silicon carbide (SiC), gallium arsenide (GaAs), gallium phosphide (GaP), indium phosphide (InP), indium arsenide (InAs), indium antimonide (InSb), silicon germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), and gallium indium arsenide phosphide (GaInAsP). Other suitable compound semiconductor materials are within the contemplated scope of the present disclosure. The compound semiconductor may have a gradient feature in which the compositional ratio thereof changes from one location to another location therein. The compound semiconductor may be formed over a silicon substrate. The compound semiconductor may be strained. In some embodiments, the semiconductor substrate 10 may include a multilayer compound semiconductor structure. In some embodiments, the semiconductor substrate 10 may be a semiconductor on insulator (SOI) (e.g., silicon germanium on insulator (SGOI)). Generally, an SOI substrate includes a layer of a semiconductor material such as epitaxial silicon, germanium, silicon germanium, or combinations thereof. Other suitable semiconductor materials are within the contemplated scope of the present disclosure. The SOI substrate may be doped with a P-type dopant, for example, but not limited to, boron (Br), aluminum (Al), or gallium (Ga). Other suitable dopant materials are within the contemplated scope of the present disclosure. Alternatively, the SOI substrate may be doped with an N-type dopant, for example, but not limited to, nitrogen (N), phosphorous (P), or arsenic (As). Other suitable dopant materials are within the contemplated scope of the present disclosure. In some embodiments, the semiconductor substrate may further include various active regions, for example, the active regions configured for an N-type metal oxide semiconductor (NMOS) transistor device or the active regions configured for a P-type metal oxide semiconductor (PMOS) transistor device. In some embodiments, the active regions may includes source/drain (S/D) regions of a transistor device. It is noted that each of the source/drain regions may refer to a source or a drain, individually or collectively dependent upon the context.

The metal layer (Mx) is disposed on the semiconductor substrate 10, and includes a dielectric layer 111 and a plurality of metal lines 112 disposed in the dielectric layer 111 and spaced apart from each other. One of the metal lines 112 is shown in FIG. 2. In some embodiments, each of the metal lines 112 includes a barrier layer 112a conformally formed on a bottom surface and a sidewall surface of a corresponding one of trenches 111a of the dielectric layer 111, a liner layer 112b conformally formed on the barrier layer 112a, and a bulk metal portion 112c disposed on the liner layer 112b opposite to the barrier layer 112a. In some embodiments, the bulk metal portion 112c may be made of a metal material. In some embodiments, the metal material for forming the bulk metal portion 112c may include, for example, but not limited to, metals (e.g., copper (Cu), silver (Ag), gold (Au), aluminum (Al), nickel (Ni), cobalt (Co), ruthenium (Ru), iridium (Ir), platinum (Pt), palladium (Pd), osmium (Os), tungsten (W), molybdenum (Mo), tantalum (Ta), or the like), alloys thereof possessing promising conductive properties, or the like. Other suitable metal materials are within the contemplated scope of the present disclosure. The liner layer 112b is used to enhance adhesion of the bulk metal portion 112c to the barrier layer 112a. In some embodiments, the liner layer 112b may include, for example, but not limited to, cobalt (Co), ruthenium (Ru), tantalum (Ta), manganese (Mn), or the like, or alloys thereof. Other suitable metal materials are within the contemplated scope of the present disclosure. The barrier layer 112a is used to prevent the metal material of the bulk metal portion 112c from diffusing into the dielectric layer 111. In some embodiments, the barrier layer 112a may include, for example, but not limited to, tantalum (Ta), zinc (Zn), manganese (Mn), zirconium (Zr), titanium (Ti), hafnium (Hf), niobium (Nb), vanadium (V), chromium (Cr), scandium (Sc), yttrium (Y), silicon (Si), tungsten (W), molybdenum (Mo), aluminum (Al), titanium nitride (TiN), titanium tungsten (TiW), tantalum nitride (TaN), tungsten nitride (WN), or combinations thereof. Other suitable materials are within the contemplated scope of the present disclosure. In some embodiments, the metal layer (Mx) is formed by a single damascene process as known to those skilled in the art of semiconductor fabrication.

The etch stop layer 12 is disposed on the metal layer (Mx). In some embodiments, the etch stop layer 12 may include, for example, but not limited to, silicon carbonitride (SiCN), silicon carbide (SiC), plasma-enhanced silicon oxide (PE-SiO₂), oxygen-doped silicon carbide (ODC), aluminum oxide (AlOx), aluminum oxynitride (AlOxN), or combinations thereof. Other suitable materials are within the contemplated scope of the present disclosure. In some embodiments, the etch stop layer 12 has a thickness ranging from about 10 Å to about 40 Å. In some embodiments, the etch stop layer 12 may be formed by a suitable deposition process as is known in the art of semiconductor fabrication, such as physical vapor deposition (PVD), chemical vapor deposition (CVD), atomic layer deposition (ALD), plasma-enhanced ALD (PEALD), thermal ALD, plasma-enhanced CVD (PECVD), or the like. Other suitable deposition techniques are within the contemplated scope of the present disclosure.

The via layer (Vx) is disposed on the etch stop layer 12, and includes a dielectric layer 131 and a plurality of conductive vias 132 disposed in the dielectric layer 131 and spaced apart from each other. One of the conductive vias 132 is shown in FIG. 2. One or more of the conductive vias 132 are connected to corresponding one(s) of the metal lines 112, respectively. In some embodiments, each of the conductive vias 132 includes a barrier layer 132a conformally formed on a bottom surface and a sidewall surface of a corresponding one of via openings 131a of the dielectric layer 131, a liner layer 132b conformally formed on the barrier layer 132a, and a bulk metal portion 132c disposed on the liner layer 132b opposite to the barrier layer 132a. The materials of the barrier layer 132a, the liner layer 132b, and the bulk metal portion 132c of the conductive vias 132 may be the same as or similar to those of the barrier layer 112a, the liner layer 112b, and the bulk metal portion 112c of the metal lines 112, respectively, and thus details thereof are omitted for the sake of brevity. In some embodiments, the via layer (Vx) is formed by a single damascene process as known to those skilled in the art of semiconductor fabrication.

In some embodiments, the glue layer 14 may be formed on the via layer (Vx) by a suitable deposition process as is known in the art of semiconductor fabrication, such as PVD, CVD, ALD, PEALD, thermal ALD, PECVD, or the like. Other suitable deposition techniques are within the contemplated scope of the present disclosure. In some embodiments, the glue layer 14 may include tantalum nitride (TaN), titanium nitride (TiN), manganese nitride (MnN), tungsten nitride (WN), or combinations thereof. Other suitable materials are within the contemplated scope of the present disclosure. In some embodiments, the glue layer 14 has a thickness ranging from about 5 Å to about 20 Å.

In some embodiments, the sacrificial metal layer 15 may be formed on the glue layer 14 by a suitable deposition process as is known in the art of semiconductor fabrication, such as PVD, CVD, ALD, PEALD, thermal ALD, PECVD, or the like. Other suitable deposition techniques are within the contemplated scope of the present disclosure. In some embodiments, the sacrificial metal layer 15 may include aluminum (Al), aluminum oxide (Al₂O₃), zinc (Zn), zinc oxide (ZnO), or combinations thereof. Other suitable materials are within the contemplated scope of the present disclosure. In some embodiments, the sacrificial metal layer 15 has a thickness ranging from about 150 Å to about 800 Å. In some embodiments, the sacrificial metal layer 15 may be formed directly on the via layer (Vx) without formation of the glue layer 14 therebelow if the sacrificial metal layer 15 has sufficient adherence to the via layer (Vx).

In some embodiments, the hard mask layer 16 may be formed on the sacrificial metal layer 15 by a suitable deposition process as is known in the art of semiconductor fabrication, such as PVD, CVD, PECVD, or the like. Other suitable deposition techniques are within the contemplated scope of the present disclosure. In some embodiments, the hard mask layer 16 may include titanium nitride (TiN), tungsten nitride (WN), tungsten carbide (WC), silicon carbonitride (SiCN), or combinations thereof. Other suitable materials are within the contemplated scope of the present disclosure. In some embodiments, the hard mask layer 16 has a thickness ranging from about 30 Å to about 80 Å.

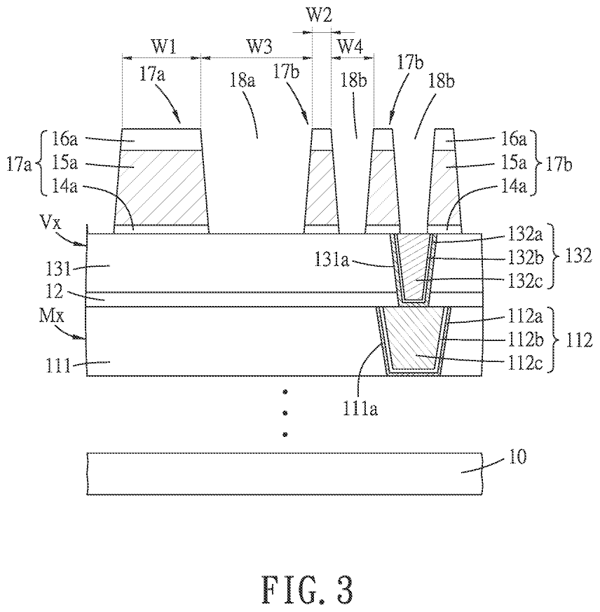

Referring to FIG. 1A and the example illustrated in FIG. 3, the method 100A proceeds to step S02, where the sacrificial stack 17 (i.e., a stack of the hard mask layer 16, the sacrificial metal layer 15, and the glue layer 14) of the structure shown in FIG. 2 is patterned by a suitable etching process as is known in the art of semiconductor fabrication to form a plurality of sacrificial stack portions 17a, 17b which are spaced apart from each other by trenches 18a, 18b. One of the sacrificial stack portions 17a and three of the sacrificial stack portions 17b are shown in FIG. 3. Each of the sacrificial stack portions 17a, 17b includes a glue portion 14a formed from the glue layer 14, a sacrificial metal portion 15a formed from the sacrificial metal layer 15 and disposed on the glue portion 14a, and a hard mask portion 16a formed from the hard mask layer 16 and disposed on the sacrificial metal portion 15a opposite to the glue portion 14a. The etching process for forming the sacrificial stack portions 17a, 17b may be performed by reactive ion etching (RIE), plasma etching, deep RIE, atomic layer etching, or the like, using an etching gas, for example, but not limited to, CHF₃, CH₂F₂, CF₄, C₄F₈, C₄F₆, N₂, Ar, O₂, NF₃, CO₂, H₂, or the like.

In some embodiments, each of the sacrificial stack portions 17a has a width (W1) ranging from about 60 nm to about 1,000 nm. In some embodiments, each of the sacrificial stack portions 17b has a width (W2) ranging from about 10 nm to about 60 nm. In some embodiments, each of the trenches 18a has a width (W3) ranging from about 60 nm to about 1,000 nm. In some embodiments, one of the trenches 18a is disposed between one of the sacrificial stack portions 17a and one of sacrificial stack portions 17b which are adjacent to each other. In some embodiments, each of the trenches 18b has a width (W4) ranging from about 10 nm to about 60 nm. In some embodiments, two adjacent ones of the sacrificial stack portions 17b are spaced apart from each other by a corresponding one of trenches 18b. In some embodiments, the sacrificial stack portions 17a, 17b have a width ranging from about 10 nm to about 1000 nm, and the trenches 18a, 18b have a width ranging from about 10 nm to about 1000 nm.

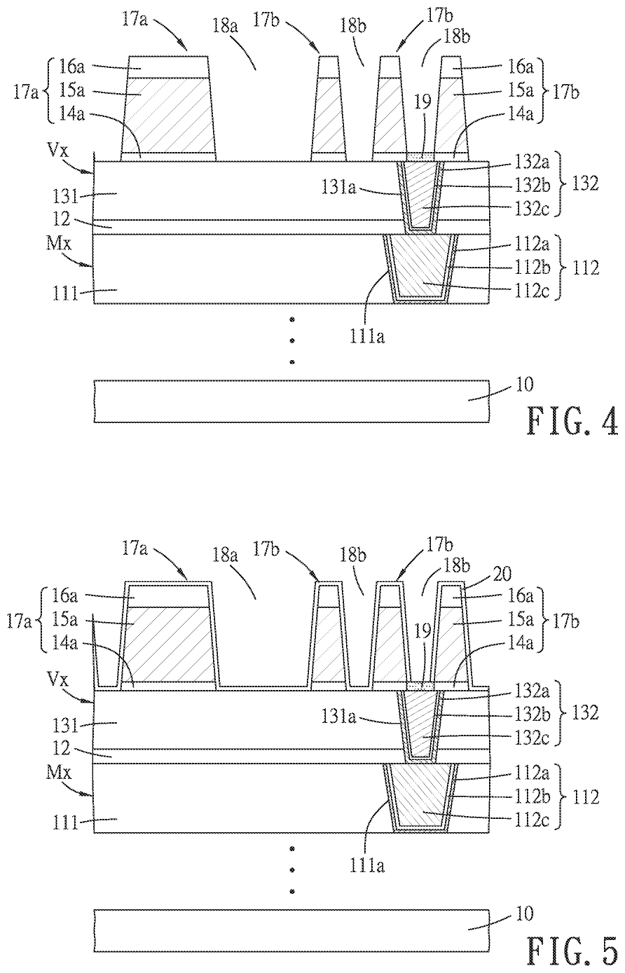

Referring to FIG. 1A and the example illustrated in FIG. 4, the method 100A proceeds to step S03, where a cap layer 19 is formed. In some embodiments, the cap layer 19 is formed on the conductive vias 132 by selectively forming a self-assembled monolayer (SAM) on the bulk metal portion 132c of each of the conductive vias 132 without formation of the SAM on the dielectric layer 131 so as to permit the SAM to serve as a blocking layer. In some embodiments, the SAM may be formed from a plurality of precursor molecules, each of which includes a head group and a tail connected to the head group. The head group of each of the precursor molecules serves as a functional group to be reacted with the metal material at an upper surface of the bulk metal portion 132c of each of the conductive vias 132 so as to form the SAM on the conductive vias 132. In some embodiments, examples of the precursor molecules include ethane-1,2-diol, hydroxybenzene, ethanoic acid, or combinations thereof. The tail of each of the precursor molecules may include, for example, but not limited to, an aliphatic chain (for example, ethyl of ethane-1,2-diol or ethanoic acid) or an aromatic chain (for example, phenyl of hydroxybenzene). A hydroxyl group of ethane-1,2-diol, hydroxybenzene, or ethanoic acid serves as the head group. In addition, any one of —NH, —NH₂, —NH₃, and —SH groups may be added into the precursor molecules so as to serve as the head group. In some embodiments, any one of —NH, —NH₂, —NH₃, and —SH groups may substitute the hydroxyl group of ethane-1,2-diol, hydroxybenzene, or ethanoic acid so as to serve as the head group. In some embodiments, the cap layer may be formed as a multi-layered configuration.

Referring to FIG. 1A and the example illustrated in FIG. 5, the method 100A proceeds to step S04, where an oxidation prevention layer 20 is formed. The oxidation prevention layer 20 is formed conformally on the sacrificial stack portions 17a, 17b and the dielectric layer 131 of the structure shown in FIG. 4 without formation on the cap layer 19 (i.e., exposure of the cap layer 19 from corresponding ones of the trenches 18b) by a suitable deposition process as is known in the art of semiconductor fabrication, such as ALD, PEALD, CVD, PECVD, or the like. Other suitable deposition techniques are within the contemplated scope of the present disclosure. In some embodiments, the oxidation prevention layer 20 may include silicon oxide (SiOx), silicon oxycarbide (SiOC), oxygen-doped silicon carbide (ODS) or combinations thereof. Other suitable materials are within the contemplated scope of the present disclosure. In some embodiments, the oxidation prevention layer 20 may have a thickness ranging from about 10 Å to about 60 Å. After the oxidation prevention layer 20 is formed, the cap layer 19 is removed by a suitable removal process as is known in the art of semiconductor fabrication, such as a plasma treatment, or the like. Other suitable removal techniques are within the contemplated scope of the present disclosure.

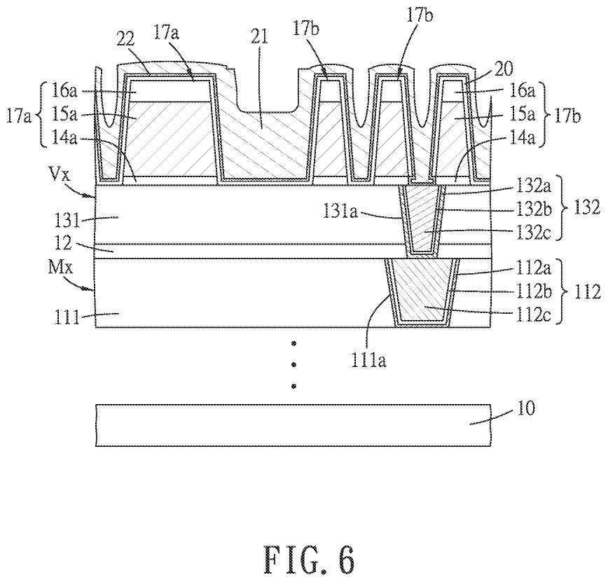

Referring to FIG. 1A and the example illustrated in FIG. 6, the method 100A proceeds to step S05, where a first metal material layer 21 is formed to fill the trenches 18a, 18b of the structure shown in FIG. 5 and is annealed to form a self-forming barrier layer 22. In some embodiments, the first metal material layer 21 may be formed on the structure shown in FIG. 5 to fill the trenches 18a, 18b and to cover the sacrificial stack portions 17a, 17b by a suitable deposition process as is known in the art of semiconductor fabrication, such as PVD, CVD, PECVD, or the like. Other suitable deposition techniques are within the contemplated scope of the present disclosure. In some embodiments, the first metal material layer 21 has a thickness ranging from about 5 nm to about 10 nm. In some embodiments, the first metal material layer 21 includes an alloy represented by AₓB_{y}, wherein x is an integer ranging from about 1 to about 5, y is an integer ranging from about 1 to about 10, A represents a first metal, B represents a second metal different from the first metal, and the first metal has a reduction potential lower than that of the second metal, such that the first metal is more easily reacted with oxygen or silicon to form a metal oxide or a metal silicide than the second metal. In some embodiments, the first metal material layer 21 includes the alloy represented by AₓB_{y}, wherein A is the first metal which includes one of aluminum (Al), chromium (Cr), manganese (Mn), zirconium (Zr), niobium (Nb), and combinations thereof, and B is the second metal which includes one of ruthenium (Ru), copper (Cu), cobalt (Co), and combinations thereof.

In some embodiments, the first metal material layer 21 is annealed by a suitable annealing process, for example, but not limited to, a rapid thermal annealing (RTA) process, a laser process, a furnace annealing process, or the like, to form the self-forming barrier layer 22. Other suitable annealing techniques are within the contemplated scope of the disclosure. In some embodiments, the annealing process may be performed at a temperature ranging from about 150° C. to about 1000° C. If the temperature is lower than 150° C., the self-forming barrier layer 22 may not be formed. If the temperature is higher than 1000° C., the dielectric layer 131, the dielectric layer 111, the semiconductor substrate 10, or the like may be damaged. As described above, the first metal material layer 21 includes the alloy of the first metal and the second metal in which the first metal is more easily reacted with oxygen or silicon to form a metal oxide or a metal silicide than the second metal. When the annealing process is performed, the first metal included in the first metal material 21 proximate to the oxidation prevention layer 20 may be reacted with oxygen or silicon to form the self-forming barrier layer 22 which includes a metal oxide, a metal silicide, or a combination thereof formed from the first metal. In some embodiments, the self-forming barrier layer 22 includes aluminum oxide (AlₓO_{y}), manganese oxide (MnₓO_{y}), zirconium oxide (ZrₓO_{y}), niobium oxide (NbₓO_{y}), aluminum silicide (Al₄Si₃), manganese monosilicide (MnSi), manganese disilicide (MnSi₂), manganese silicide (Mn₅Si₃), zirconium disilicide (ZrSi₂), trichromium silicide (Cr₃Si), chromium silicide (Cr₅Si₃), chromium monosilicide (CrSi), chromium disilicide (CrSi₂), or combinations thereof. In some embodiments, the self-forming barrier layer 22 has a thickness ranging from about 5 Å to about 20 Å.

In some embodiments, a glue layer (not sown) may be conformally formed on the oxidation prevention layer 20 and the conductive vias 132 before the self-forming barrier layer 22 is formed so as to enhance the adhesion of the self-forming barrier layer 22 to the oxidation prevention layer 20 and the conductive vias 132. In some embodiments, the glue layer may be formed by a suitable deposition process as is known in the art of semiconductor fabrication, such as ALD, PEALD, or the like. Other suitable deposition techniques are within the contemplated scope of the present disclosure. In some embodiments, the glue layer has a thickness ranging from about 0 Å to about 20 Å. In some embodiments, the glue layer may include tantalum (Ta), tantalum nitride (TaN), titanium nitride (TiN), tungsten nitride (WN), zirconium nitride (ZrN), or combinations thereof. Other suitable materials are within the contemplated scope of the present disclosure.

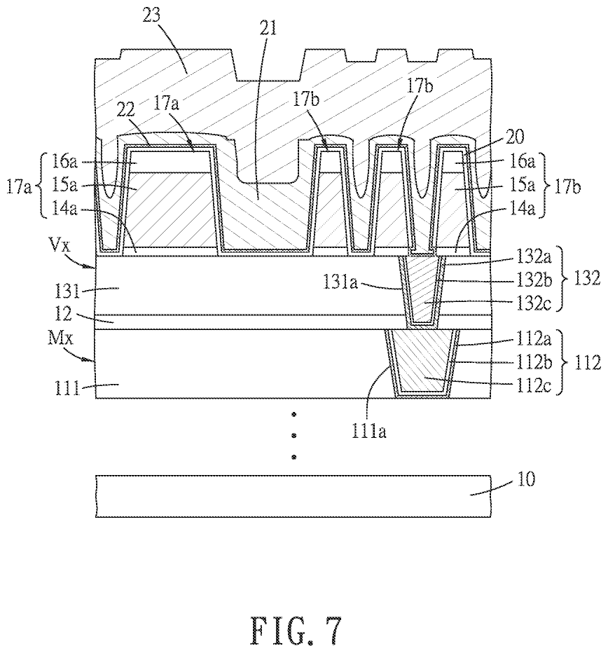

Referring to FIG. 1A and the example illustrated in FIG. 7, the method 100A proceeds to step S06, where a second metal material layer 23 is formed on the first metal material layer 21. In some embodiments, the second metal material layer 23 may be formed on the first metal material layer 21 of the structure shown in FIG. 6 by a suitable deposition process as is known in the art of semiconductor fabrication, such as PVD, electrochemical plating (ECP), or the like. Other suitable deposition techniques are within the contemplated scope of the present disclosure. In some embodiments, the second metal material layer 23 has a thickness ranging from about 1000 Å to about 6000 Å. In some embodiments, the second metal material layer 23 includes copper (Cu), cobalt (Co), ruthenium (Ru), molybdenum (Mo), tungsten (W), or combinations thereof.

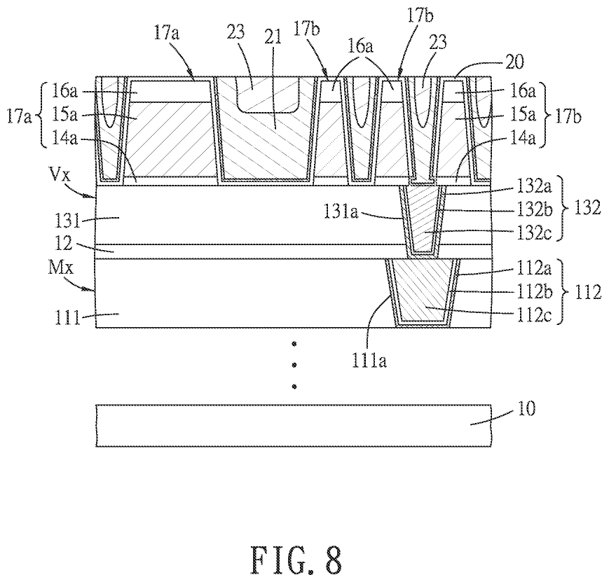

Referring to FIG. 1A and the example illustrated in FIG. 8, the method 100A proceeds to step S07, where a first planarization process is performed. The first planarization process is performed on the structure shown in FIG. 7 to remove a portion of the second metal material layer 23, a portion of the first metal material layer 21, and a portion of the self-forming barrier layer 22 to expose a top portion of the oxidation prevention layer 20. In other words, the oxidation prevention layer 20 serves as an etch stop layer for the first planarization process. In some embodiments, the first planarization process is performed by a bulk chemical mechanical planarization (CMP). In some embodiments, the bulk CMP is performed using a CMP system with operation conditions of a rotation speed of a turn table ranging from about 30 rpm (revolutions per minute) to about 130 rpm, a rotation speed of a top ring ranging from about 20 rpm to about 120 rpm, and a head down force ranging from about 0.5 psi to 2.75 psi. If the rotation speed of the turn table is lower than 30 rpm or the rotation speed of the top ring is lower 20 rpm, a removal rate of the materials to be moved by the CMP system and a uniformity of an upper surface of the structure shown in FIG. 8 will be inferior. If the rotation speed of the turn table is higher than 130 rpm or the rotation speed of the top ring is higher 120 rpm, the structure sown in FIG. 8 formed after the bulk CMP may have scratch defects. The termination of the bulk CMP may be determined using an eddy current end-point detection. In some embodiments, the bulk CMP is performed using a slurry. In some embodiments, the slurry includes a composition of an abrasive, an oxidant, a surfactant, and a metal corrosion inhibitor. In some embodiments, the abrasive includes silicon oxide (SiO₂), cerium oxide (CeO₂), aluminum oxide (Al₂O₃), or the like, or combinations thereof. In some embodiments, the oxidant includes hydrogen peroxide (H₂O₂), orthoperiodic acid (H₅IO₆), sodium hypochlorite (NaClO), or the like, or combinations thereof. In some embodiments, the surfactant includes sodium dodecyl sulfate (SDS), cetyl trimethyl ammonium bromide (CTAB), octyl phenol ethoxylate (Triton X-1000), or the like, or combinations thereof. In some embodiments, the metal corrosion inhibitor includes benzotriazole (BTA), methyl benzotriazole (MBTA), 1,2,4-triazole, 2-amino-2-thiazoline, 2-pyrrolidinone, mercaptobenzothiazole, or the like, or combinations thereof. In some embodiments, the slurry has an abrasive concentration ranging from about 1% to about 4%. In some embodiments, the slurry has an oxidant concentration ranging from about 0.1% to about 4%. In some embodiments, the slurry has a pH value ranging from about 3 to about 10. In some embodiments, the slurry selectivity of the second metal material layer 23 or the first metal material layer 21 to the oxidation prevention layer 20 is greater than about 10.

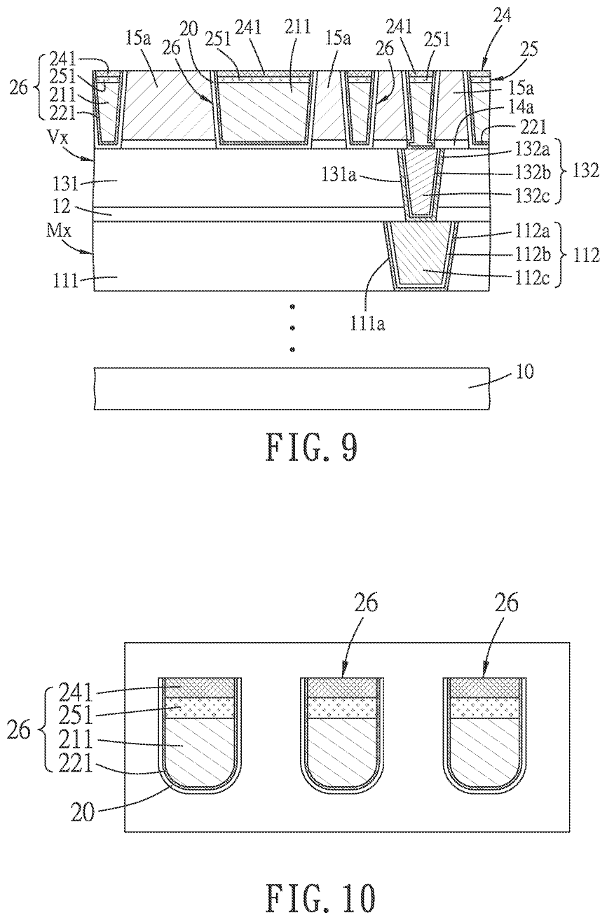

Referring to FIG. 1A and the example illustrated in FIG. 9, the method 100A proceeds to step S08, where a second planarization process is performed. The second planarization process is performed on the structure shown in FIG. 8 to remove a portion of the oxidation prevention layer 20, the hard mask portion 16a of each of the sacrificial stack portions 17a, 17b, and the second metal material layer 23 to expose the sacrificial metal portion 15a of each of the sacrificial stack portions 17a, 17b. In some embodiments, the second planarization process is performed by a buffing CMP. In some embodiments, the buffing CMP is performed using a CMP system with operation conditions of a rotation speed of a turn table ranging from about 60 rpm to about 90 rpm, a rotation speed of a top ring ranging from about 50 rpm to about 80 rpm, and a head down force ranging from about 0.5 psi to 2.0 psi. If the rotation speed of the turn table is lower than 60 rpm or the rotation speed of the top ring is lower 50 rpm, a removal rate of the materials to be moved by the CMP system and a uniformity of an upper surface of the structure shown in FIG. 9 will be inferior. If the rotation speed of the turn table is higher than 90 rpm or the rotation speed of the top ring is higher 80 rpm, the structure sown in FIG. 9 formed after the buffing CMP may have scratch defects. The termination of the buffing CMP may be determined using an eddy current end-point detection. In some embodiments, the buffing CMP is performed using a slurry. In some embodiments, the slurry includes a composition of an abrasive, an oxidant, a surfactant, and a metal corrosion inhibitor. In some embodiments, the abrasive includes silicon oxide (SiO₂), titanium oxide (TiO₂), aluminum oxide (Al₂O₃), or the like, or combinations thereof. In some embodiments, the oxidant, the surfactant, and the metal corrosion inhibitor in the slurry for the buffing CMP may be respectively the same as or similar to the oxidant, the surfactant, and the metal corrosion inhibitor in the slurry for the bulk CMP, and thus details thereof are omitted for the sake of brevity. In some embodiments, the concentrations of the abrasive and the oxidant in the slurry for the buffing CMP may be respectively the same as or similar to the concentrations of the abrasive and the oxidant in the slurry for the bulk CMP, and thus details thereof are omitted for the sake of brevity. In some embodiments, the second metal material layer 23, the first metal material layer 21, the oxidation prevention layer 20, and the sacrificial metal portion 15a and the hard mask portion 16a of each of the sacrificial stack portions 17a, 17b have substantially the same slurry selectivity. In the second planarization process, a self-forming etch stop layer 24 is formed by oxidation of the first metal (for example, but not limited to, aluminum (Al), chromium (Cr), manganese (Mn), zirconium (Zr), niobium (Nb), or combinations thereof) of a top portion of remainder of the first metal material layer 21 and includes an oxide of the first metal. The self-forming etch stop layer 24 includes a plurality of self-forming etch stop portions 241. In some embodiments, each of the self-forming etch stop portions 241 has a thickness ranging from about 20 Å to 50 Å. In addition, a transition layer 25 is formed below the self-forming etch stop layer 24. The transition layer 25 includes the first metal and the oxide of the first metal and has an oxygen concentration lower than that of the self-forming etch stop layer 24. The transition layer 25 includes a plurality of transition portions 251 disposed below the self-forming etch stop portions 241, respectively. In some embodiments, each of the transition portions 251 has a thickness ranging from about 10 Å to about 40 Å. The first metal material layer 21 is formed into a plurality of bulk metal portions 211, and the self-forming barrier layer 22 is formed into a plurality of the self-forming barriers 221. After the second planarization process, a plurality of metal line structures 26 are formed to be spaced apart from each other. Each of the metal line structures 26 includes one of the bulk metal portions 211, a corresponding one of the transition portions 251 disposed on the one of the bulk metal portions 211, a corresponding one of the self-forming etch stop portions 241 disposed on the corresponding one of the transition portions 251 the opposite to the one of the bulk metal portions 211, a corresponding one of the self-forming barriers 221 laterally covering the one of the bulk metal portions 211, the corresponding one of the transition portions 251, and the corresponding one of the self-forming etch stop portions 241 and covering a bottom surface of the one of the bulk metal portions 211. The oxidation prevention layer 30 laterally covers the metal line structures 26 and also covers bottom surfaces of the metal line structures 26.

Referring to FIG. 10, in some embodiments, each of the bulk metal portions 211 is formed with a rounded lower part surrounded by a lower part of a corresponding one of the self-forming barriers 221.

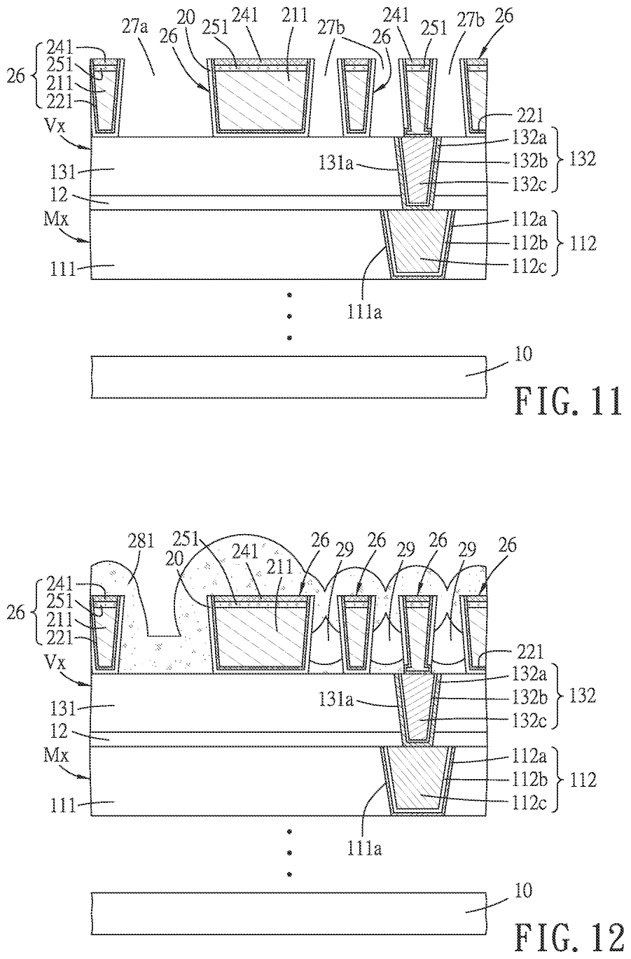

Referring to FIG. 1B and the example illustrated in FIG. 11, the method 100A proceeds to step S09, where the sacrificial metal layer 15 and the glue layer 14 are removed. In some embodiments, the sacrificial metal layer 15 (i.e., the sacrificial metal portions 15a) and the glue layer 14 (i.e., the glue portions 14a) are removed using an oxidant so as to form trenches 27a, 27b. In some embodiments, the oxidant includes hydrogen peroxide (H₂O₂). In some embodiments, the hydrogen peroxide has a pH value ranging from about 9 to about 12. When the sacrificial metal layer 15 and the glue layer 14 are removed using the oxidant, the metal line structures 26 can be protected by the oxidation prevention layer 20 from being damaged by the oxidant. The self-forming etch stop portion 241 of each of the metal line structures 26 remains after the sacrificial metal layer 15 and the glue layer 14 are removed using the oxidant. Each of the trenches 27a, 27b has a height ranging from about 150 Å to about 850 Å. Each of the trenches 27b has a width smaller than that of the trench 27a. The width of each of the trenches 27a, 27b decreases gradually in a direction from a lower surface to an upper surface of each of the metal line structures 26. An upper end of each of the trenches 27b has a width less than about 35 nm.

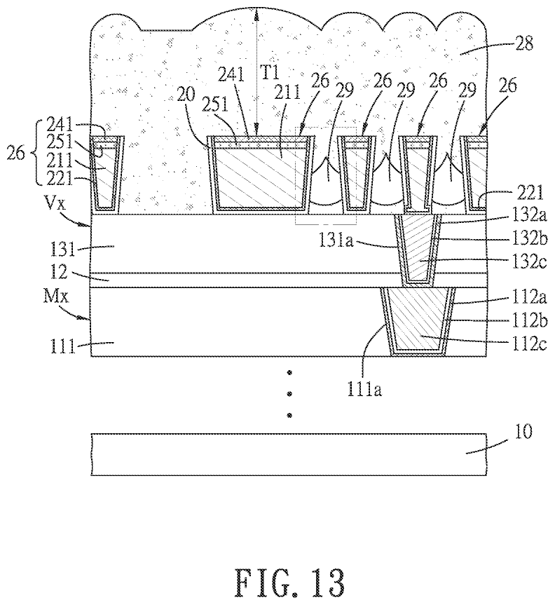

Referring to FIG. 1B and the examples illustrated in FIGS. 12 and 13, the method 100A proceeds to step S10, where a dielectric layer 28 is formed. Referring to the example illustrated in FIG. 12, a dielectric material 281 for forming the dielectric layer 28 (see FIG. 13) is deposited on the structure shown in FIG. 11 by a suitable deposition process as is known in the art of semiconductor fabrication, such as PVD, CVD, or the like, to form a plurality of air gaps 29 in the trenches 27b (see FIG. 11). Other suitable deposition techniques are within the contemplated scope of the present disclosure. In some embodiments, the dielectric material 281 may include silicon oxide (SiO₂), silicon oxycarbide (SiOC), other low-k (low dielectric constant) materials, or the like. As described above, each of the trenches 27b has a width smaller than that of the trench 27a, the width of each of the trenches 27b decreases gradually in the direction from the lower surface to the upper surface of each of the metal line structures 26, and the upper end of each of the trenches 27b has a width less than about 35 nm. Therefore, the air gaps 29 are formed in the trenches 27b and the trenches 27a may be fully filled with the dielectric material 281 without formation of the air gaps 29 therein.

Referring to the example illustrated in FIG. 13, the dielectric material 281 is further deposited by a suitable deposition process as is known in the art of semiconductor fabrication, such as PVD, CVD, spin-on deposition, or the like, to form the dielectric layer 28. Other suitable deposition techniques are within the contemplated scope of the present disclosure. In some embodiments, the dielectric layer 28 has a thickness (T1) above the metal lines structures 26 in a range from about 800 Å to about 2000 Å.

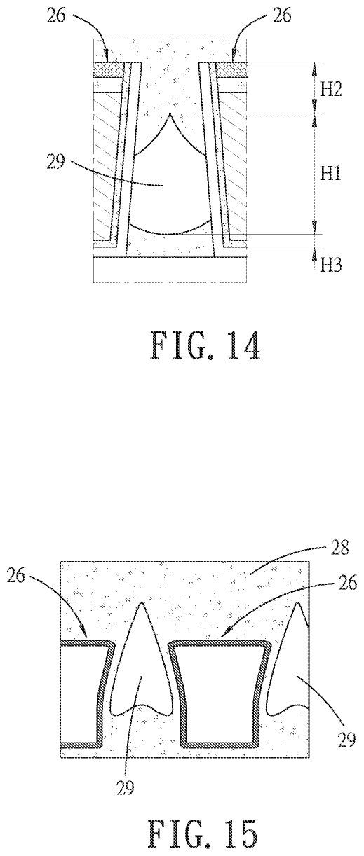

In some embodiments, the air gaps 29 may have a droplet-like shape as shown in FIG. 14 or an inverted heart-like shape as shown in FIG. 15. Referring to the example illustrated in FIG. 14, in some embodiments, the air gap 29 may have a maximum vertical height (H1) ranging from about 70 Å to about 750 Å. In some embodiments, a vertical height (H2) between an upper end surface of the metal line structure 26 and an upper end of the air gap 29 ranges from about 10 Å to about 50 Å. In some embodiments, a vertical height (H3) between a lower end surface of the metal line structure 26 and a lower end of the air gap 29 ranges from about 0 Å to about 30 Å. Referring to the example illustrated in FIG. 15, in some embodiments, the upper end of the air gap 29 is higher than the upper end surface of the metal line structure 26.

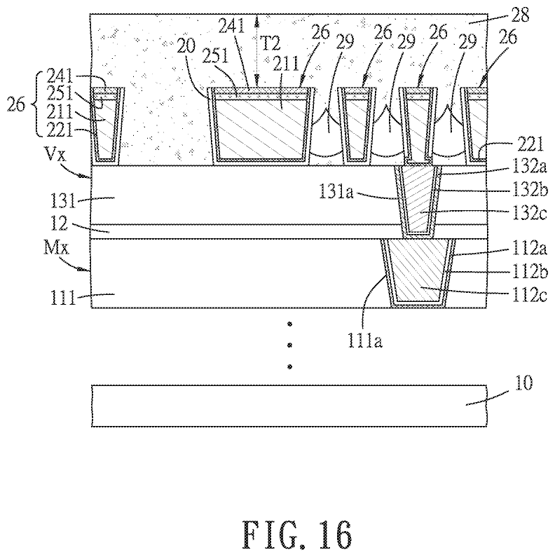

Referring to FIG. 1B and the example illustrated in FIG. 16, the method 100A proceeds to step S11, where a third planarization process is performed on the dielectric layer 28 of the structure shown in FIG. 13 so as to form the dielectric layer 28 with an upper flat surface. In some embodiments, the third planarization process may be performed by the buffering CMP described above with reference to FIG. 9, and thus details thereof are omitted for the sake of brevity. In some embodiments, the termination of the buffing CMP may be determined using an optical critical dimension (OCD) metrology tool. In some embodiments, the dielectric layer 28 after the third planarization has a thickness (T2) above the metal lines structures 26 (i.e., a thickness between the upper flat surface of the dielectric layer 28 and the upper end surface of the metal line structures 26) in a range from about 300 Å to about 1600 Å.

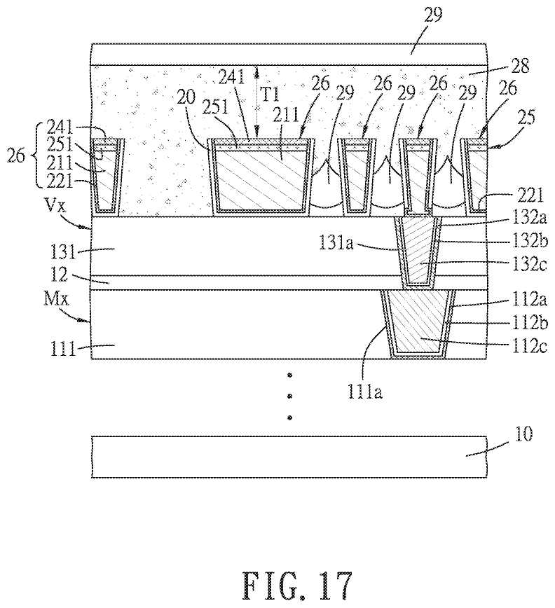

Referring to FIG. 1B and the example illustrated in FIG. 17, the method 100A proceeds to step S12, where an etch stop layer 29 is formed. In some embodiments, the etch stop layer 29 may be formed on the upper flat surface of the dielectric layer 28 of the structure shown in FIG. 16 using the material and process for forming the etch stop layer 12 described above with reference to FIG. 2, and thus details thereof are omitted for the sake of brevity.

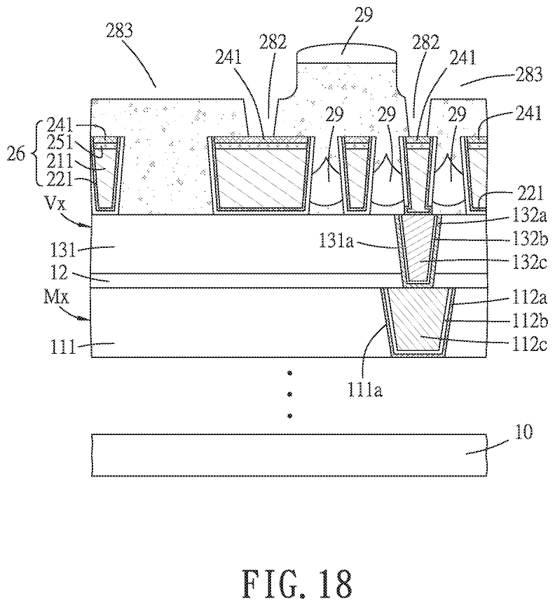

Referring to FIG. 1B and the examples illustrated in FIGS. 18 to 20, the method 100A proceeds to step S13, wherein a plurality of interconnect structures 30 (see FIG. 20) are formed. The semiconductor device 200A is obtained accordingly. As shown in FIG. 20, the interconnect structures 30 are formed in an upper portion of the dielectric layer 28, and includes a plurality of via structures 31 and a plurality of metal line structures 32. Some of the via structures 31 extend downwardly from corresponding ones of the metal line structures 32 and respectively penetrate through the self-forming etch stop portions 241 to respectively terminate at the transition portions 251. One or more of the via structures 31 are configured to permit corresponding one or more of the metal line structures 32 to be connected to corresponding one or more of the metal line structures 26, respectively therethrough. In some embodiments, each of the interconnect structures 30 includes a barrier layer 30a, a liner layer 30b conformally formed on the barrier layer 30a, and a bulk metal portion 30c disposed on the liner layer 30b opposite to the barrier layer 30a. The semiconductor device 200A includes the metal layer (Mₓ), the via layer (Vx) disposed on the metal layer (Mₓ), a metal layer (Mₓ₊₁) disposed on the via layer (Vₓ) opposite to the metal layer (Mₓ), and an interconnect layer disposed on the metal layer (Mₓ₊₁) opposite to the via layer (Vₓ). The interconnect layer includes a via layer (Vₓ₊₁) disposed on the metal layer (Mₓ₊₁) opposite to the via layer (Vₓ) and a metal layer (Mₓ₊₂) disposed on the via layer (Vₓ₊₁) opposite to the metal layer (Mₓ₊₁). The metal layer (Mₓ₊₁) includes a lower portion of the dielectric layer 28 and the metal line structures 26 disposed in the lower portion of the dielectric layer 28 and spaced apart from each other. The interconnect layer is disposed in the upper portion of the dielectric layer 28, and the interconnect structures 30 are disposed in the upper portion of the dielectric layer 28 and are spaced apart from each other. Lower portions of the interconnect structures 30 respectively serve as the via structures 31 of the via layer (Vₓ₊₁), and upper portions of the interconnect structures 30 respectively serve as the metal lines structures 32 of the metal layer (Mₓ₊₂). The upper portion and the lower portion of the dielectric layer 28 are formed integrally and are in direct contact with each other without the formation of an etch stop layer therebetween.

In some embodiments, the interconnect layer including the interconnect structures 30 are formed using a dual damascene process. In some embodiments, the dual damascene process is performed according the steps described below.

Referring to the example illustrated in FIG. 18, a plurality of via openings 282 and a plurality of trenches 283 are formed by patterning the etch stop layer 29 and the dielectric layer 28 of the structure shown in FIG. 17 using one or more etching processes (for example, but not limited to, a dry etching process, a wet etching process, or a combination thereof) through a pattern of opening formed in a patterned mask layer (not shown) disposed on the etch stop layer 29, so as to expose a plurality of the self-forming etch stop portions 241 from corresponding ones of the via openings 282 and corresponding ones of the trenches 283. In some embodiments, the one or more etching processes may be performed using a fluorine-based etching gas.

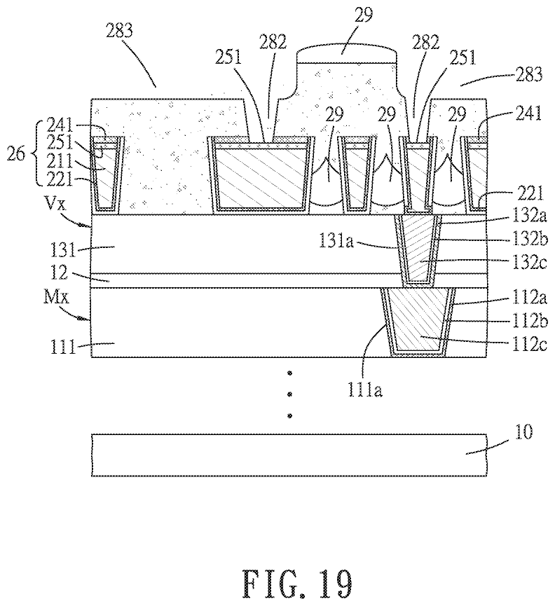

Referring to the example illustrated in FIG. 19, the self-forming etch stop portions 241 exposed from the corresponding ones of the via openings 282 and the corresponding ones of the trenches 283a are removed by a wet cleaning process so as to expose a plurality of the transition portions 251 from the corresponding ones of the via openings 282 and the corresponding ones of the trenches 283a. In some embodiments, the wet cleaning process is performed using a cleaning agent. In some embodiments, the cleaning agent has a pH value ranging from about 3 to about 10, and includes hydrogen peroxide at a concentration ranging from about 0% to about 10%.

Referring to the example illustrated in FIG. 20, a barrier material layer for forming the barrier layer 30a is conformally formed in the trenches 283 and the via opening 282 by a suitable deposition process as is known to those skilled in the art of semiconductor fabrication, for example, PVD, CVD, PECVD, ALD, PEALD, or the like. Other suitable deposition techniques are within the contemplated scope of the disclosure. A liner material layer for forming the liner layer 30b is conformally formed on the barrier material layer by a suitable deposition process as is known to those skilled in the art of semiconductor fabrication, for example, PVD, CVD, PECVD, ALD, PEALD, or the like. Other suitable deposition techniques are within the contemplated scope of the disclosure. A metal material layer for forming the bulk metal portion 30c is filled into the trenches 283 and the via openings 282 by a suitable deposition process as is known to those skilled in the art of semiconductor fabrication, for example, PVD, CVD, PECVD, ALD, PEALD, electroless deposition (ELD), electro-chemical plating (ECP), or the like, and a planarization treatment (e.g., CMP) is then performed to form the interconnect structures 30 shown in FIG. 20. The materials for forming the barrier layer 30a, the liner layer 30b, and the bulk metal portion 30c are the same as or similar to those of the barrier layer 112a, the liner layer 112b, and the bulk metal portion 112c of the metal lines 112, respectively with reference to FIG. 2, and thus details thereof are omitted for the sake of brevity.

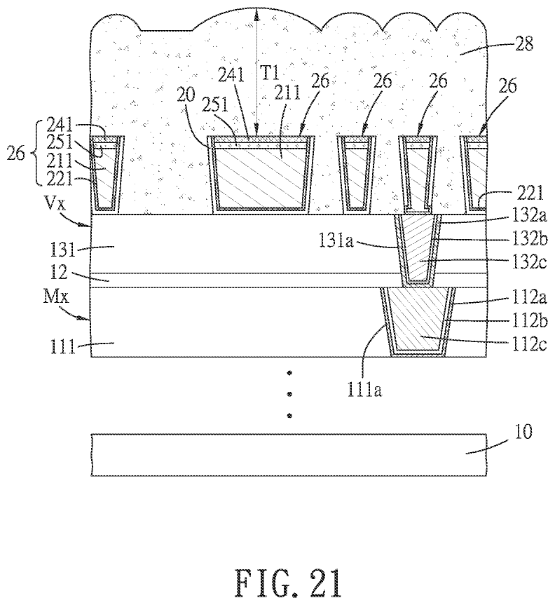

Referring to the example illustrated in FIG. 21, when step S10 of FIG. 1B (i.e., formation of the dielectric layer 28) is performed by spin-on deposition using silicon oxide (SiO₂), other low-k dielectric material, a flowable low-k dielectric material, or the like, the trenches 27a, 27b of the structure shown in FIG. 11 are fully filled with the dielectric material without formation of air gaps among the metal line structures 26.

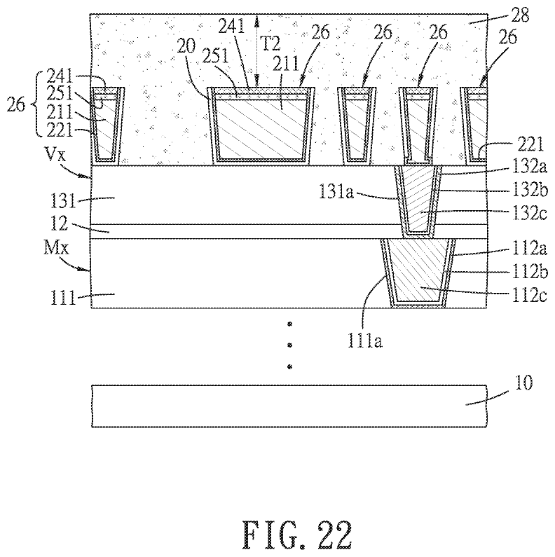

Referring to the examples illustrated in FIGS. 22 to 26, the structure shown in FIG. 21 is processed using steps S11, S12, and S13 of FIG. 1B. Details of steps S11, S12, and S13 are described above with reference to FIGS. 16 to 20, and are omitted for the sake of brevity.

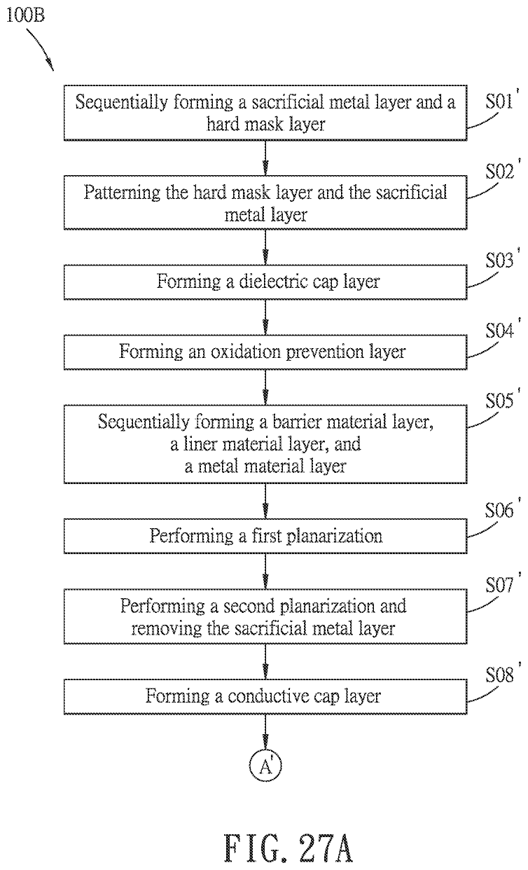

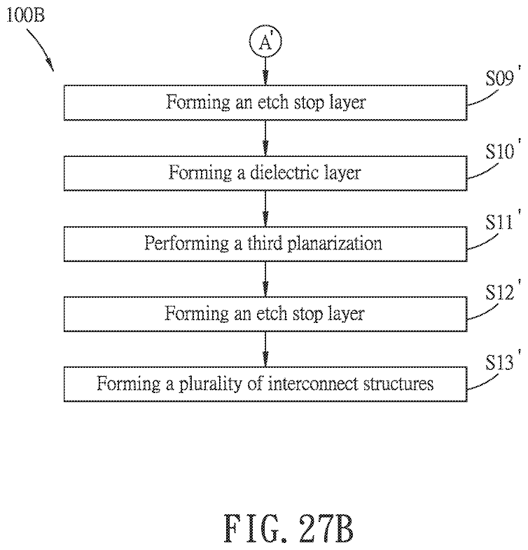

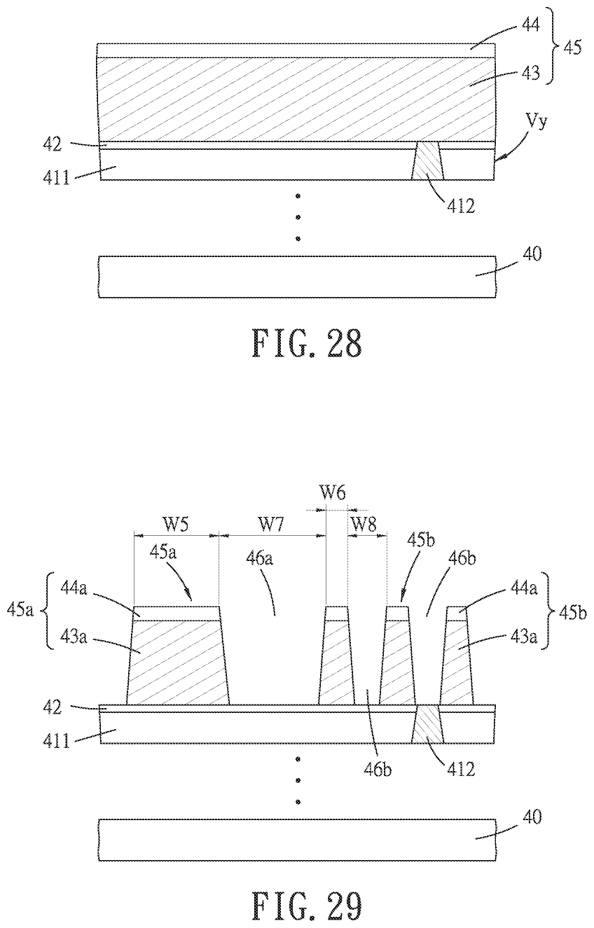

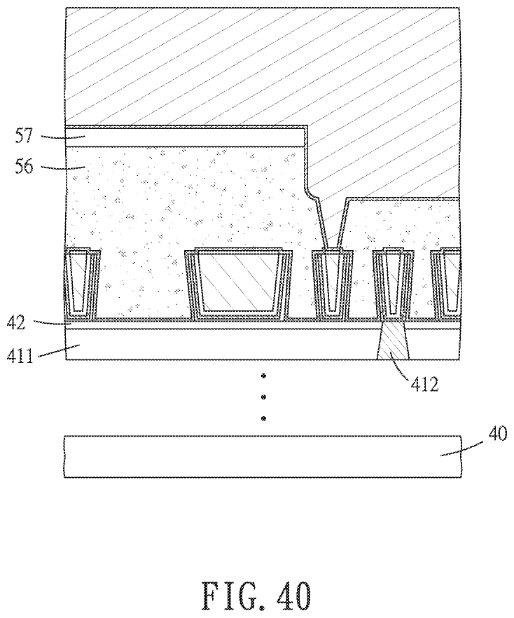

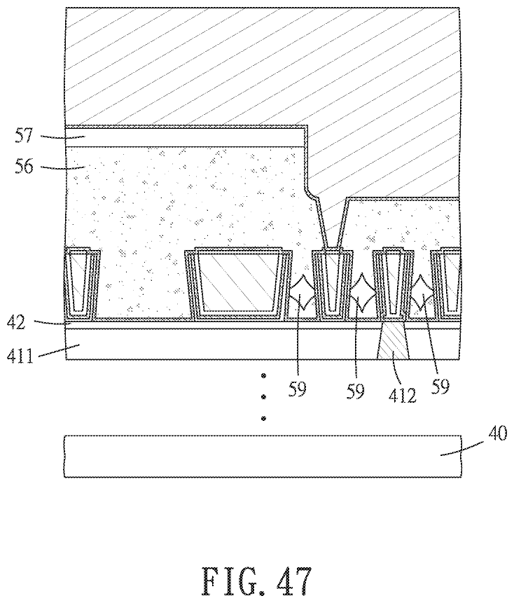

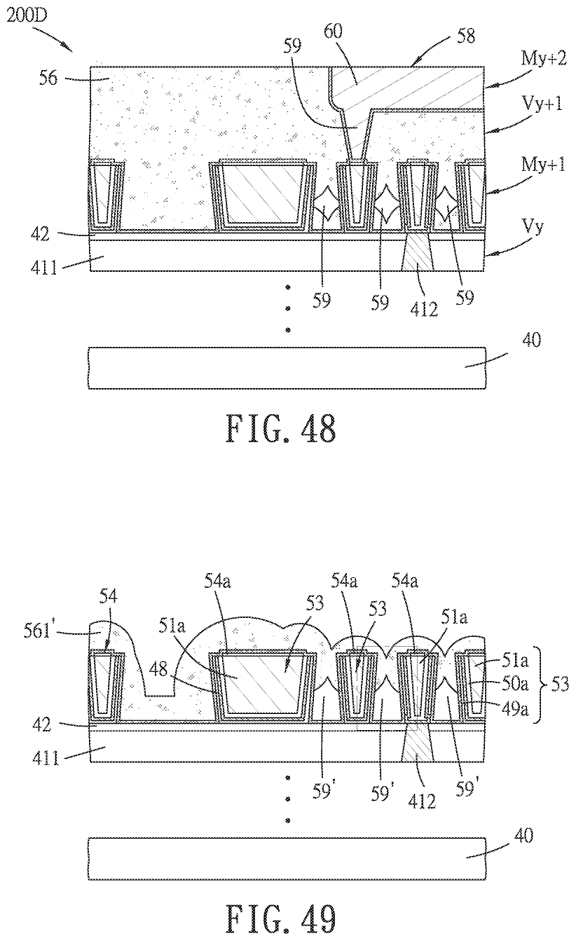

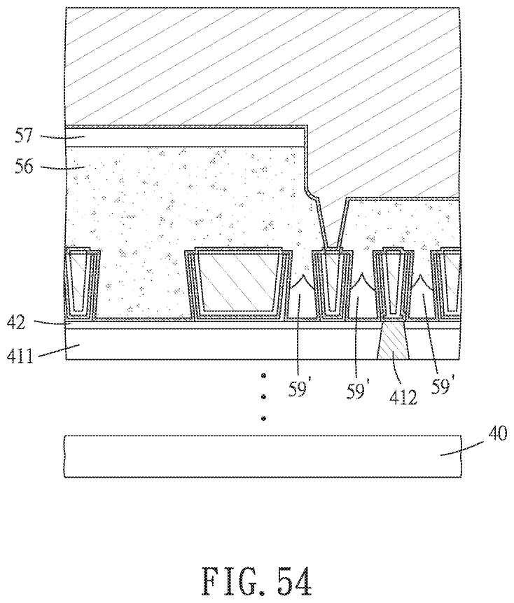

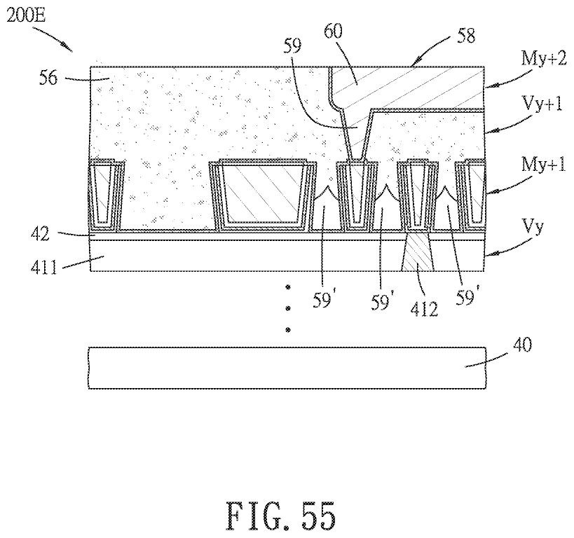

FIGS. 27A and 27B are flow diagrams illustrating a method 100B for manufacturing a semiconductor device (for example, a semiconductor device 200C shown in FIG. 41, a semiconductor device 200D shown in FIG. 48, and a semiconductor device 200E shown in FIG. 55) in accordance with some embodiments. FIGS. 28 to 55 illustrate schematic views of some intermediate stages of the method 100B in accordance with some embodiments. Some portions may be omitted in FIGS. 28 to 55 for the sake of brevity. Additional steps can be provided before, after or during the method 100B, and some of the steps described herein may be replaced by other steps or be eliminated. Similarly, further additional features may be present in the semiconductor device 200C, the semiconductor device 200D, and the semiconductor device 200E, and/or features present may be replaced or eliminated in additional embodiments.

Referring to FIG. 27A and the example illustrated in FIG. 28, the method 100B begins at step S01′, where a sacrificial metal layer 43 and a hard mask layer 44 are formed sequentially. In some embodiments, the sacrificial metal layer 43 and the hard mask layer 16 are formed sequentially on an etch stop layer 42 disposed on a via layer (V_{y}). The via layer (V_{y}) is disposed on a semiconductor substrate 40. The sacrificial metal layer 43 and the hard mask layer 44 are collectively referred to as a sacrificial stack 45.

The via layer (V_{y}) includes a dielectric layer 411 and a plurality of conductive vias 412 disposed in the dielectric layer 411 and spaced apart from each other. One of the conductive vias 412 is shown in FIG. 28. In some embodiments, the substrate 40, the via layer (V_{y}), and the etch stop layer 42 may be respectively the same as or similar to the semiconductor substrate 10, the via layer (Vₓ), and the etch stop layer 12 described above with reference to FIG. 2, and thus details thereof are omitted for the sake of brevity. In some embodiments, the glue layer 14 described above with reference to FIG. 2 may be formed between the etch stop layer 42 and the sacrificial metal layer 43 so as to enhance adhesion of the sacrificial metal layer 43 to the etch stop layer 42.

Referring to FIG. 27A and the example illustrated in FIG. 29, the method 100B proceeds to step S02′, where the sacrificial stack 45 (i.e., a stack of the hard mask layer 44 and the sacrificial metal layer 43) of the structure shown in FIG. 28 is patterned by a suitable etching process as is known in the art of semiconductor fabrication to form a plurality of trenches 46a, 46b and a plurality of sacrificial stack portions 45a, 45b spaced apart from each other by the trenches 46a, 46b. One of the sacrificial stack portions 45a and three of the sacrificial stack portions 45b are shown in FIG. 29. Each of the sacrificial stack portions 45a, 45b includes a sacrificial metal portion 43a formed from the sacrificial metal layer 43 and disposed on etch stop layer 42, and a hard mask portion 44a formed from the hard mask layer 44 and disposed on the sacrificial metal portion 43a opposite to the etch stop layer 42. The techniques for patterning the sacrificial stack 45 to form the sacrificial stack portions 45a, 45b may be the same as or similar to those described above with reference to FIG. 3, and thus details thereof are omitted for the sake of brevity.

In some embodiments, each of the sacrificial stack portions 45a has a width (W5) ranging from about 60 nm to about 1,000 nm. In some embodiments, each of the sacrificial stack portions 45b has a width (W6) ranging from about 10 nm to about 60 nm. In some embodiments, each of the trenches 46a has a width (W7) ranging from about 60 nm to about 1,000 nm. In some embodiments, one of the trenches 46a is disposed between one of the sacrificial stack portions 45a and one of the sacrificial stack portions 45b which are adjacent to each other. In some embodiments, each of the trenches 46b has a width (W8) ranging from about 10 nm to about 60 nm. In some embodiments, two adjacent ones of the sacrificial stack portions 45b are spaced apart from each other by a corresponding one of trenches 46b.

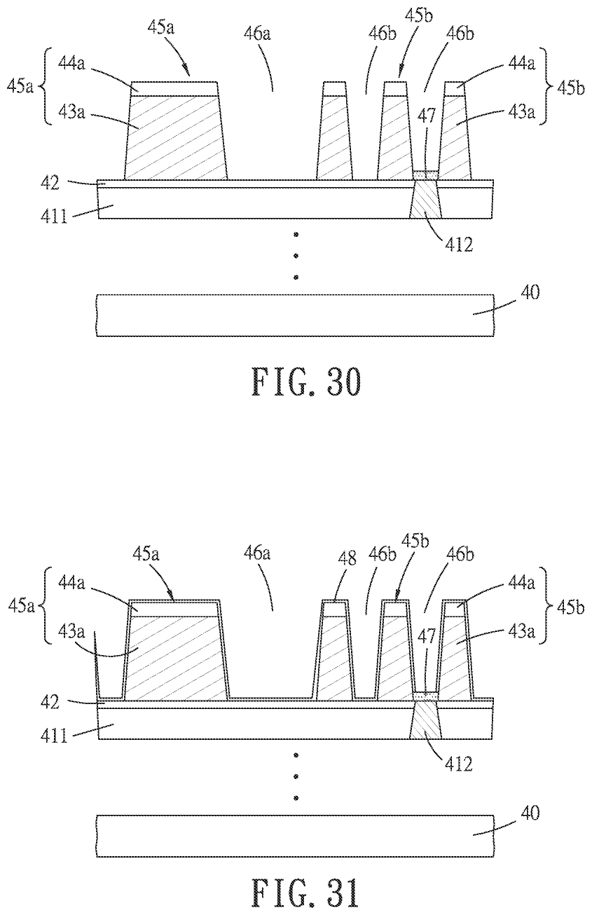

Referring to FIG. 27A and the example illustrated in FIG. 30, the method 100B proceeds to step S03′, where a dielectric cap layer 47 is formed. In some embodiments, the dielectric cap layer 47 is formed on the conductive vias 412 by selectively forming a self-assembled monolayer (SAM) on the conductive vias 412 without formation of the SAM on the etch stop layer 42 so as to permit the SAM to serve as a blocking layer. The techniques for forming the dielectric cap layer 47 may be the same as or similar to those described above with reference to FIG. 4, and thus details thereof are omitted for the sake of brevity.

Referring to FIG. 27A and the example illustrated in FIG. 31, the method 100B proceeds to step S04′, where an oxidation prevention layer 48 is formed. The oxidation prevention layer 48 is formed conformally on the sacrificial stack portions 45a, 45b and the etch stop layer 42 of the structure shown in FIG. 30 without any formation on the dielectric cap layer 47. The techniques for forming the oxidation prevention layer 48 may be the same as or similar to those described above with reference to FIG. 5, and thus details thereof are omitted for the sake of brevity. After the oxidation prevention layer 48 is formed, the dielectric cap layer 47 is removed by a suitable removal process as is known in the art of semiconductor fabrication, such as a plasma treatment, or the like. Other suitable removal techniques are within the contemplated scope of the present disclosure.

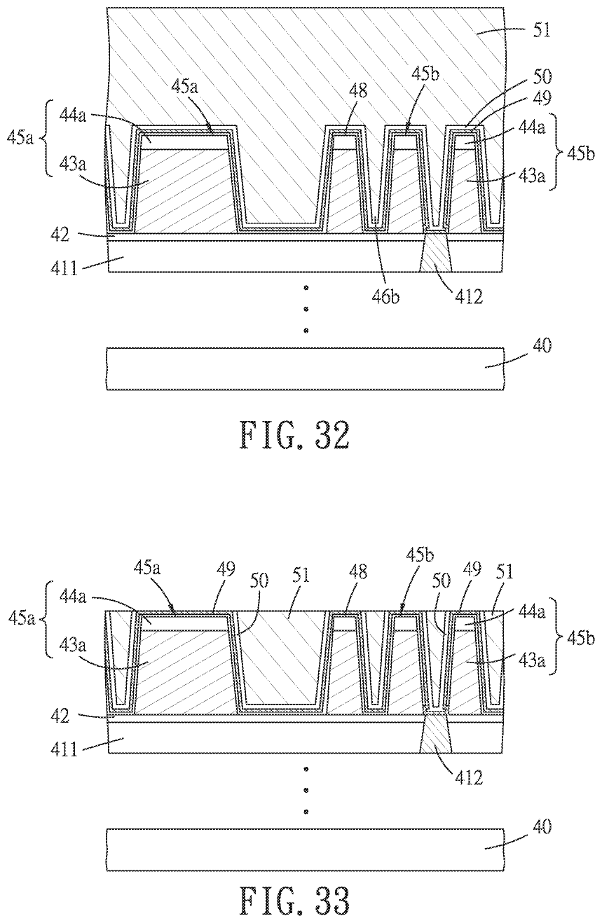

Referring to FIG. 27A and the example illustrated in FIG. 32, the method 100B proceeds to step S05′, where a barrier material layer 49, a liner material layer 50, and a metal material layer 51 are formed sequentially on the structure shown in FIG. 31. Processes for forming the barrier material layer 49, the liner material layer 50, and the metal material layer 51 are the same as or similar to those described above with reference to FIG. 20, and thus details thereof are omitted for the sake of brevity. In some embodiments, a seed material layer (not shown) can be conformally formed on the liner material layer 50 before the metal material layer 51 is formed. In some embodiments, the seed material layer may be formed by a suitable deposition process as is known to those skilled in the art of semiconductor fabrication, for example, PVD, CVD, PECVD, or the like. Other suitable deposition techniques are within the contemplated scope of the disclosure. In some embodiments, the barrier material layer 49 includes, for example, but not limited to, tantalum (Ta), tantalum nitride (TaN), titanium nitride (TiN), tungsten nitride (WN), nickel nitride (NiN), manganese nitride (MnN), or combinations thereof. Other suitable materials are within the contemplated scope of the disclosure. In some embodiments, the liner material layer 50 includes, for example, but not limited to, cobalt (Co), ruthenium (Ru), platinum (Pt), gold (Au), manganese (Mn), or combinations thereof. Other suitable materials are within the contemplated scope of the disclosure. In some embodiments, the seed material layer includes, for example, but not limited to, copper (Cu), cobalt (Co), molybdenum (Mo), tungsten (W), ruthenium (Ru), aluminum (Al), silver (Ag), or combinations thereof. Other suitable materials are within the contemplated scope of the disclosure. In some embodiments, the metal material layer 51 include, for example, but not limited to, copper (Cu), cobalt (Co), ruthenium (Ru), tungsten (W), molybdenum (Mo), silver (Ag), rhodium (Rh), iridium (Ir), or combinations thereof. Other suitable materials are within the contemplated scope of the disclosure. In some embodiments, the barrier material layer 49 has a thickness ranging from about 0 Å to about 30 Å. In some embodiments, the liner material layer 50 has a thickness ranging from about 10 Å to about 40 Å. In some embodiments, the metal material layer has a thickness ranging from about 2000 Å to about 8000 Å.

Referring to FIG. 27A and the example illustrated in FIG. 33, the method 100B proceeds to step S06′, where a first planarization process is performed. The first planarization process is performed on the structure shown in FIG. 32 to remove a portion of the metal material layer 51 and a portion of the liner material layer 50 to expose a top portion of the barrier material layer 49. In some embodiments, the first planarization process is performed by a bulk CMP. Details for the bulk CMP are described above with reference to FIG. 8, and thus are omitted for the sake of brevity.

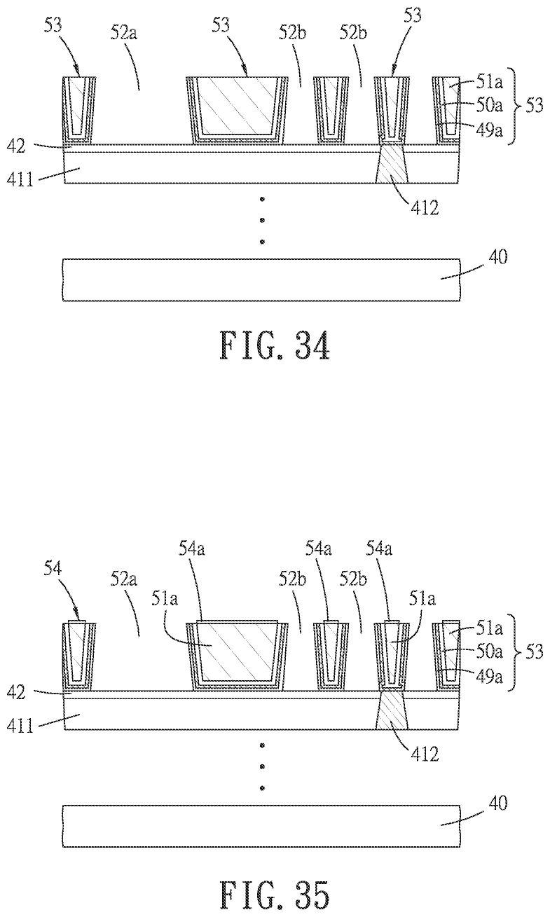

Referring to FIG. 27A and the example illustrated in FIG. 34, the method 100B proceeds to step S07′, where a second planarization process is performed and the sacrificial metal layer 43 is removed. The second planarization process is performed on the structure shown in FIG. 33 to remove a portion of the barrier material layer 49, a portion of the liner material layer 50, a portion of the oxidation prevention layer 48, the hard mask portion 44a of each of the sacrificial stack portions 45a, 45b, and a portion of the metal material layer 51 to expose the sacrificial metal portion 43a of each of the sacrificial stack portions 45a, 45b. In some embodiments, the second planarization process is performed by a buffing CMP. Details for the buffing CMP are described above with reference to FIG. 9, and thus are omitted for the sake of brevity. The sacrificial metal layer 43 (i.e., the sacrificial metal portion 43a of each of the sacrificial stack portions 45a, 45b) is then removed. In some embodiments, the sacrificial metal portion 43a of each of the sacrificial stack portions 45a, 45b is removed using an oxidant so as to form a plurality of trenches 52a, 52b and a plurality of metal line structures 53 spaced apart from each other by the trenches 52a, 52b. Each of the trenches 52b has a width smaller than that of each of the trenches 52a. In some embodiments, the oxidant includes hydrogen peroxide (H₂O₂). In some embodiments, the hydrogen peroxide has a pH value ranging from about 9 to about 11. When the sacrificial metal portion 43a of each of the sacrificial stack portions 45a, 45b is removed using the oxidant, the metal line structures 53 can be protected by the oxidation prevention layer 48 from being damaged by the oxidant. Each of the metal line structures 53 includes a bulk metal portion 51a formed from the metal material layer 51, a liner layer 50a formed from the liner material layer 50 and covering a lateral surface and a bottom surface of the bulk metal portion 51a, and a barrier layer 49a formed from the barrier material layer 49 and separated from the bulk metal portion 51a by the liner layer 50a.

Referring to FIG. 27A and the example illustrated in FIG. 35, the method 100B proceeds to step S08′, where a conductive cap layer 54 is formed. In some embodiments, the conductive cap layer 54 is directly formed on the bulk metal portion 51a of each of the metal line structures 53 by a suitable selective deposition process as is known to those skilled in the art of semiconductor fabrication, for example, selective CVD, selective PECVD, or the like. Other suitable selective deposition techniques are within the contemplated scope of the disclosure. The conductive cap layer 54 includes a plurality of conductive cap portions 54a, each of which cover the bulk metal portions 51a of a corresponding one of the metal line structures 53. In some embodiment, the conductive cap layer 54 includes, for example, but not limited to, cobalt (Co), ruthenium (Ru), platinum (Pt), gold (Au), manganese (Mn), or combinations thereof. In some embodiments, the cap layer 54 has a thickness ranging from about 10 Å to 40 Å.

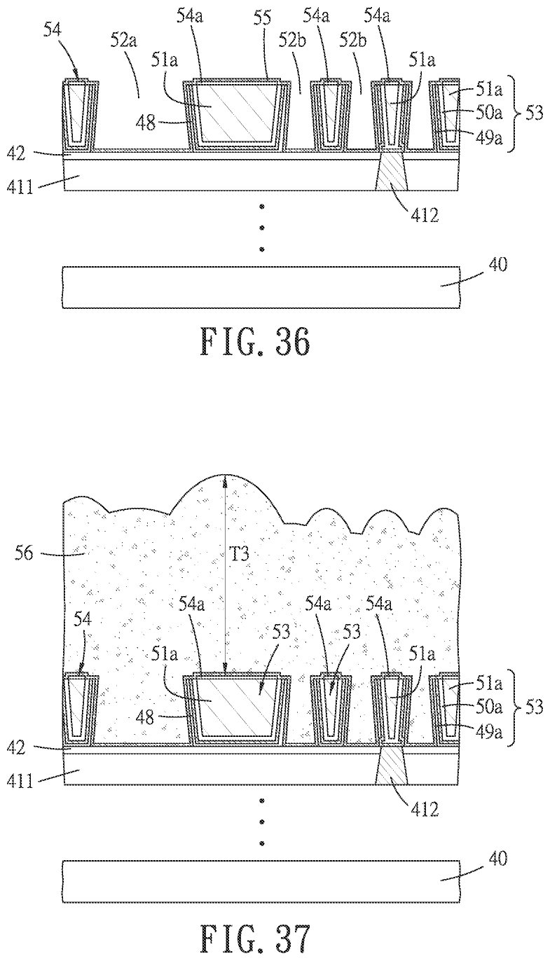

Referring to FIG. 27B and the example illustrated in FIG. 36, the method 100B proceeds to step S09′, where an etch stop layer 55 is formed. In some embodiments, the etch stop layer 55 is conformally formed on the structure shown in FIG. 35 by a suitable deposition process as is known to those skilled in the art of semiconductor fabrication, for example, ALD, PEALD, CVD, PECVD, or the like to cover the conductive cap portions 54a, the oxidation prevention layer 48, and the etch stop layer 42. Other suitable deposition techniques are within the contemplated scope of the disclosure. In some embodiments, the etch stop layer 55 includes, for example, but not limited to, silicon carbonitride (SiCN), silicon carbide (SiC), plasma-enhanced silicon oxide (PE-SiO₂), oxygen-doped silicon carbide (ODC), aluminum oxide (AlOx), aluminum oxynitride (AlOxN), aluminum nitride (AlN), or combinations thereof. Other suitable materials are within the contemplated scope of the disclosure. In some embodiments, the etch stop layer 55 has a thickness ranging from about 10 Å to about 50 Å.

Referring to FIG. 27B and the example illustrated in FIG. 37, the method 100B proceeds to step S10′, where a dielectric layer 56 is formed. In some embodiments, the dielectric layer 56 is formed on the structure shown in FIG. 36 by spin-on deposition using silicon oxide (SiO₂), other low-k dielectric material, a flowable low-k dielectric material, or the like, such that the trenches 52a, 52b of the structure shown in FIG. 36 are fully filled with silicon oxide (SiO₂), the other low-k dielectric material, the flowable low-k dielectric material, or the like without formation of air gaps among the metal line structures 53. In some embodiments, the dielectric layer 56 has a thickness (T3) above the metal lines structures 53 in a range from about 800 Å to about 2000 Å.

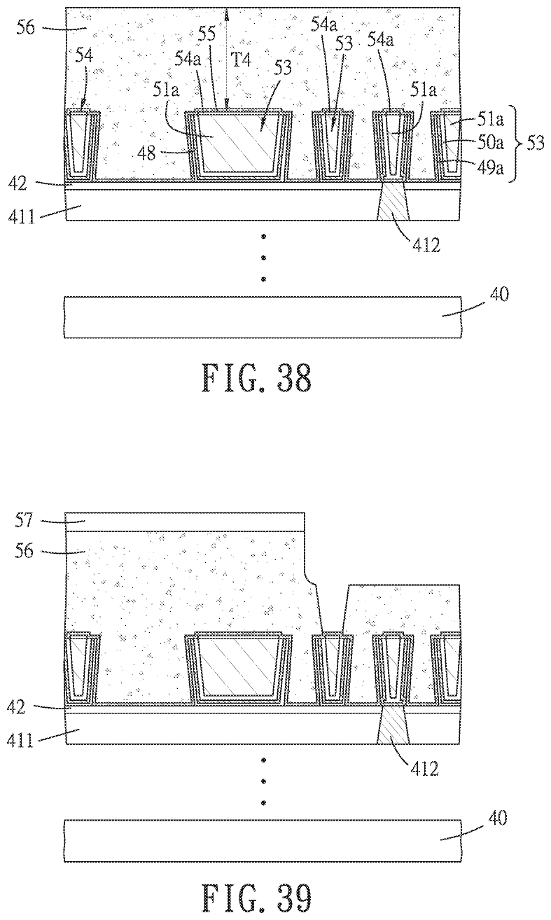

Referring to FIG. 27B and the example illustrated in FIG. 38, the method 100B proceeds to step S11′, where a third planarization process is performed on the dielectric layer 56 of the structure shown in FIG. 37 so as to form the dielectric layer 56 with an upper flat surface. In some embodiments, the third planarization process may be performed by the buffering CMP described above with reference to FIG. 9, and thus details thereof are omitted for the sake of brevity. In some embodiments, the dielectric layer 56 after the third planarization has a thickness (T4) above the etch stop layer 55 disposed on the metal lines structures 53 in a range from about 300 Å to about 1600 Å.

Referring to FIG. 27B and the examples illustrated in FIGS. 39 to 41, the method 100B proceeds to step S12′, where an etch stop layer 57 is formed, and step S13′, where a plurality of interconnect structures 58 is formed. One of the interconnect structures 58 is shown in FIG. 41. The interconnect structures 58 are formed in an upper portion of the dielectric layer 56, and includes a plurality of via structures 59 and a plurality of metal line structures 60. Some of the via structures 59 extend downwardly from corresponding ones of the metal line structures 60 and penetrate through the etch stop layer 55 to respectively terminate at the conductive cap portions 54a. One or more of the via structures 59 are configured to permit corresponding one or more of the metal line structures 60 to be connected to corresponding one or more of the metal line structures 53, respectively therethrough. Formation of the etch stop layer 75 is the same as or similar to formation of the etch stop layer 12 described above with reference to FIG. 2, and formation of the interconnect structures 58 is similar to formation of the interconnect structures 30 described above with reference to FIGS. 18 to 20, and thus details thereof are omitted for the sake of brevity. The semiconductor device 200C is obtained accordingly. The semiconductor device 200C includes the via layer (Vy), a metal layer (M_{y+1}) disposed on the via layer (V_{y}), and an interconnect layer disposed on the metal layer (M_{y+1}) opposite to the via layer (V_{y}). The interconnect layer includes a via layer (V_{y+1}) disposed on the metal layer (M_{y+1}) opposite to the via layer (V_{y}) and a metal layer (M_{y+2}) disposed on the via layer (V_{y+1}) opposite to the metal layer (M_{y+1}). The metal layer (M_{y+1}) includes a lower portion of the dielectric layer 56 and the metal line structures 53 disposed in the lower portion of the dielectric layer 56 and spaced apart from each other. The interconnect layer includes the upper portion of the dielectric layer 56 and the interconnect structures 58 disposed in the upper portion of the dielectric layer 56 and spaced apart from each other. Lower portions of the interconnect structures 58 respectively serve as the via structures 59 of the via layer (V_{y+1}), and upper portions of the interconnect structures 58 respectively serve the metal lines structures 60 of the metal layer (M_{y+2}). The upper portion and the lower portion of the dielectric layer 56 are formed integrally and are in direct contact with each other without the formation of an etch stop layer therebetween.

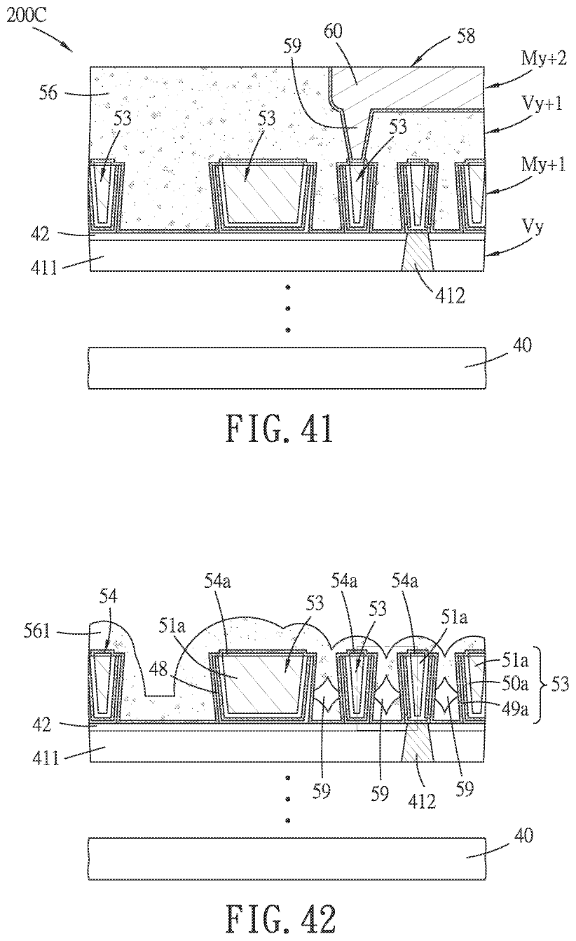

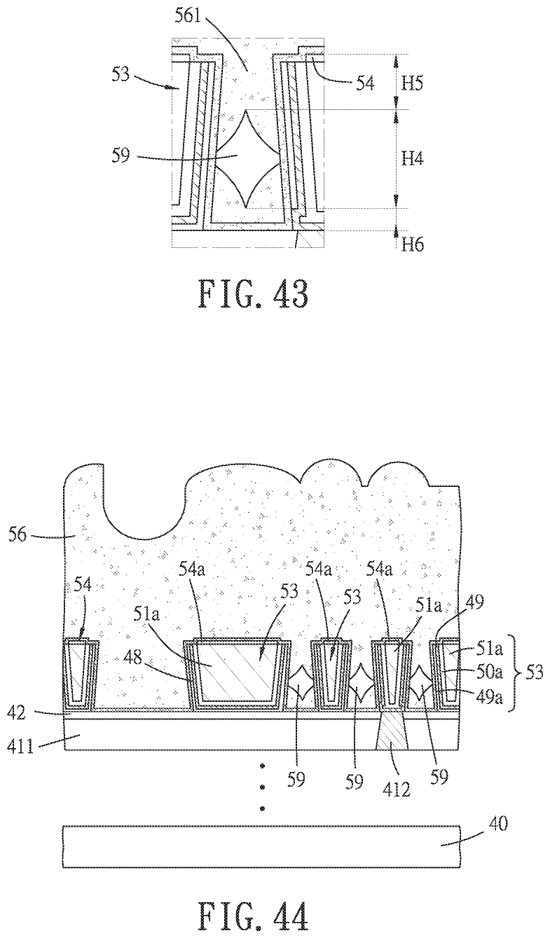

Referring to the examples illustrated in FIGS. 42 to 44, when step S10′ of FIG. 27B (i.e., formation of the dielectric layer 56) is performed by CVD using a dielectric material 561 (see FIG. 42) of silicon oxide (SiO₂), other low-k dielectric material, or the like, a plurality of air gaps 59 are formed in the trenches 52b (see FIG. 36) and among the metal line structures 53. In some embodiments, the air gaps 59 may have a rhombus-like shape as shown in FIGS. 42 and 43. Referring to the example illustrated in FIG. 43, in some embodiments, the air gap 59 may have a maximum vertical height (H4) ranging from about 70 Å to about 720 Å. In some embodiments, a vertical height (H5) between an upper end surface of the cap layer 54 and an upper end of the air gap 59 ranges from about 10 Å to about 50 Å. In some embodiments, a vertical height (H6) between a lower end surface of the metal line structure 53 and a lower end of the air gap 59 ranges from about 10 Å to about 30 Å.

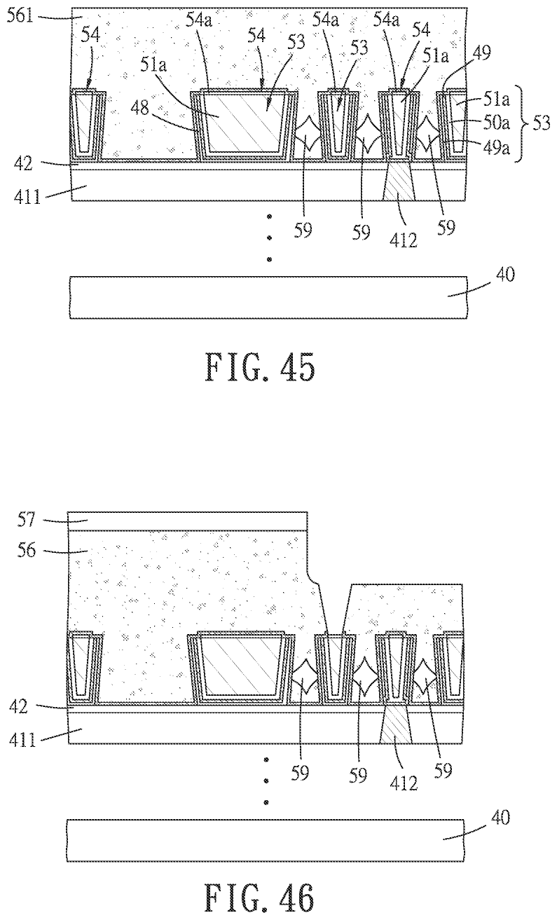

Referring to the examples illustrated in FIGS. 45 to 48, the structure shown in FIG. 44 is processed using steps S11′, S12′, and S13′ of FIG. 27B. Details of steps S11′, S12′, and S13′ are described above with reference to FIGS. 38 to 41, and are omitted for the sake of brevity. The semiconductor device 200D is obtained accordingly. The semiconductor device 200D has a configuration similar to that of the semiconductor device 200C shown in 41 and is formed with the air gaps 59.

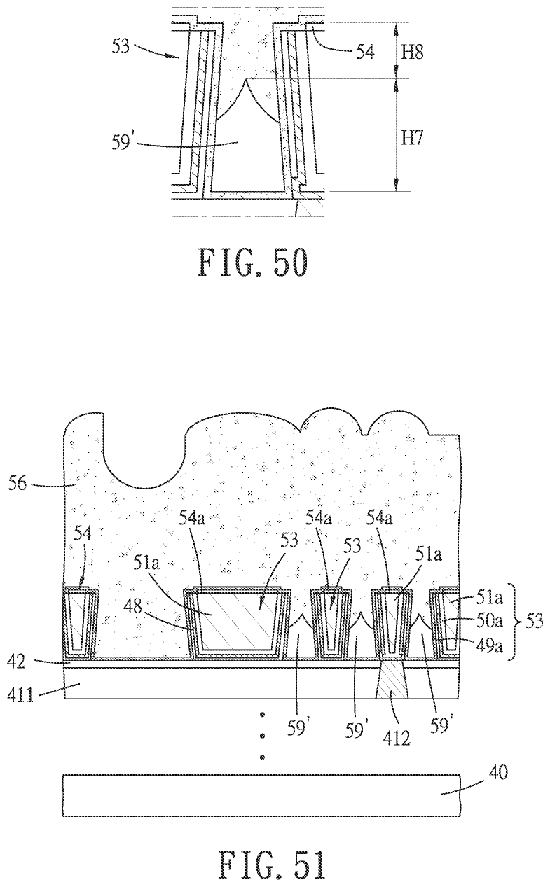

Referring to the examples illustrated in FIGS. 49 to 51, when step S10′ of FIG. 27B (i.e., formation of the dielectric layer 56) is performed by PVD using the dielectric material 561′ (see FIG. 49) of silicon oxide (SiO₂), other low-k dielectric material, or the like, a plurality of air gaps 59′ are formed in the trenches 52b (see FIG. 36) and among the metal line structures 53. In some embodiments, the air gaps 59′ may have a pentagon-like shape as shown in FIGS. 49 and 50. Referring to the example illustrated in FIG. 50, in some embodiments, the air gap 59′ may have a maximum vertical height (H7) ranging from about 100 Å to about 750 Å. In some embodiments, a vertical height (H8) between an upper end surface of the cap layer 54 and an upper end of the air gap 59′ ranges from about 10 Å to about 50 Å.

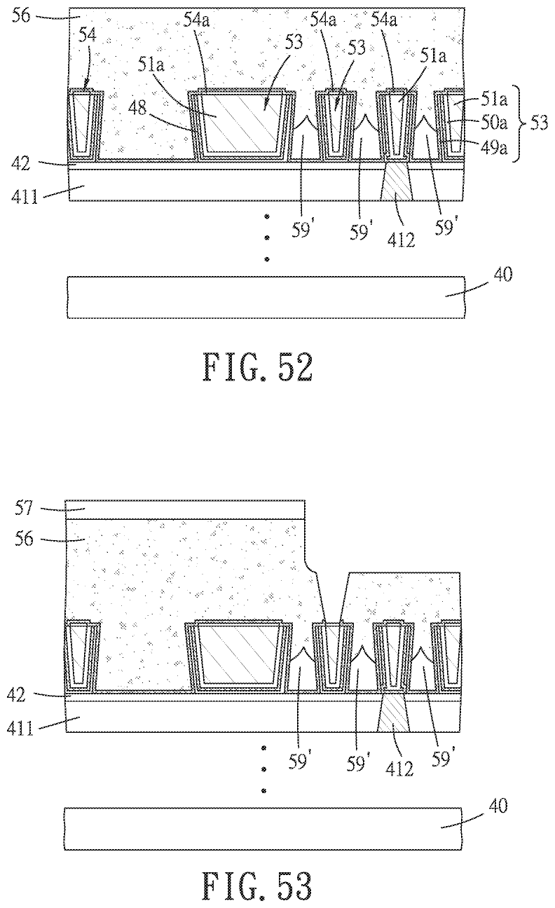

Referring to the examples illustrated in FIGS. 52 to 55, the structure shown in FIG. 51 is processed using steps S11′, S12′, and S13′ of FIG. 27B. Details of steps S11′, S12′, and S13′ are described above with reference to FIGS. 38 to 41, and are omitted for the sake of brevity. The semiconductor device 200E is obtained accordingly. The semiconductor device 200E has a configuration similar to that of the semiconductor device 200C shown in 41 and is formed with the air gaps 59′.

In a method for manufacturing a semiconductor device in accordance with some embodiments of the present disclosure, a self-forming barrier layer is formed by annealing a metal material layer which includes an alloy of a first metal and a second metal to permit the first metal to be formed into a metal oxide or a metal silicide, and a self-forming etch stop layer is formed by oxidation of the first metal in a buffing CMP. It is not necessary to additionally form a barrier layer for forming metal lines and additionally form an etch stop layer before forming an interconnect structure on the metal lines. Therefore, the resistance and the capacitance of the semiconductor device are decreased such that resistance-capacitance (RC) time delay can be reduced. Additionally, a sacrificial metal layer is used for forming the metal lines. Trenches formed among the metal lines after removing the sacrificial metal layer have a specific width which is conducive for forming air gaps among the metal lines.

In a method for manufacturing a semiconductor device in accordance with some embodiments of the present disclosure, it is not necessary to additionally form an etch stop layer between a metal layer formed with metal line structure and an interconnect layer formed with interconnect structures Therefore, the resistance and the capacitance of the semiconductor device are decreased such that resistance-capacitance (RC) time delay can be reduced. Additionally, a sacrificial metal layer is used for forming the metal lines. Trenches formed among the metal lines after removing the sacrificial metal layer have a specific width which is conducive for forming air gaps among the metal lines.

In accordance with some embodiments of the present disclosure, a method for manufacturing a semiconductor device includes: forming a plurality of sacrificial stack portions on a semiconductor substrate, the sacrificial stack portions being spaced apart from each other; forming a metal material layer to cover the sacrificial stack portions, the metal material layer including a first metal and a second metal different from the first metal, the first metal having a reduction potential lower than that of the second metal; and annealing the metal material layer to form a self-forming barrier layer conformally covering the sacrificial stack portions, the self-forming barrier layer including a metal oxide, a metal silicide, or a combination thereof formed from the first metal by annealing.

In accordance with some embodiments of the present disclosure, each of the sacrificial stack portions includes a sacrificial metal portion and a hard mask portion disposed on the sacrificial metal portion opposite to the semiconductor substrate. The method for manufacturing a semiconductor device further includes removing the hard mask portions of the sacrificial stack portions by a planarization process to expose the sacrificial metal portions of the sacrificial stack portions and to form a plurality of metal line structures spaced apart from each other by the sacrificial metal portions. Each of the metal line structures includes a bulk metal portion, a self-forming etch stop portion disposed on the bulk metal portion, and a self-forming barrier formed from the self-forming barrier layer to laterally cover the bulk metal portion and the self-forming etch stop portion and to cover a bottom surface of the bulk metal portion. The self-forming etch stop portion includes a metal oxide formed by oxidation of the first metal in the planarization process.

In accordance with some embodiments of the present disclosure, the method for manufacturing a semiconductor device further includes before formation of the sacrificial stack portions, forming a via layer on the semiconductor substrate, the via layer including a via structure exposing from a first trench formed between two corresponding ones of the sacrificial stack portions; and after formation of the sacrificial stack portions, selectively forming a cap layer on the via structure, conformally forming an oxidation prevention layer on the sacrificial stack portions such that the cap layer is exposed, and removing the cap layer to expose the via structure to be connected to a corresponding one of the metal line structures.

In accordance with some embodiments of the present disclosure, the method for manufacturing a semiconductor device further includes removing the sacrificial metal portions to form a plurality of second trenches among the metal line structures, each of the second trenches having a width decreasing gradually in a direction from a lower surface to an upper surface of each of the metal line structures; and forming a dielectric layer to cover the metal line structures, the dielectric layer including a lower dielectric layer portion and an upper dielectric layer portion disposed on and in direct contact with the lower dielectric layer portion.

In accordance with some embodiments of the present disclosure, an upper end of each of the second trenches has a width less than 35 nm. The dielectric layer is formed by physical vapor deposition or chemical vapor deposition using a low-k dielectric material including silicon oxide, silicon oxycarbide, or a combination thereof, such that a plurality of air gaps are formed among the metal line structures.

In accordance with some embodiments of the present disclosure, the first metal proximate to the oxidation prevention layer is subjected to oxidation, siliconization, or a combination thereof in annealing the metal material layer, such that the self-forming barrier layer is conformally formed on the oxidation prevention layer.

In accordance with some embodiments of the present disclosure, the planarization process is performed by a buffing chemical mechanical planarization using a slurry including an oxidant, such that the oxidation of the first metal in the planarization process is performed by the oxidant.

In accordance with some embodiments of the present disclosure, the metal material layer includes an alloy represented by AₓB_{y}, wherein x is an integer ranging from 1 to 5, y is an integer ranging from 1 to 10, A represents the first metal including one of aluminum, chromium, manganese, zirconium, niobium, and combinations thereof, and B represents the second metal including one of ruthenium, copper, cobalt, and combinations thereof.

In accordance with some embodiments of the present disclosure, the metal line structures are formed in the lower dielectric layer portion of the dielectric layer. The method for manufacturing a semiconductor device further includes forming a plurality of interconnect structures in the upper dielectric layer portion of the dielectric layer, such that at least one of the interconnect structures is respectively connected to at least one of the metal line structures.

In accordance with some embodiments of the present disclosure, a method for manufacturing a semiconductor device includes: forming a plurality of sacrificial stack portions on a semiconductor substrate, the sacrificial stack portions being spaced apart from each other; forming a plurality of metal line structures among the sacrificial stack portions such that two adjacent ones of the metal line structures are spaced apart from each other by a corresponding one of the sacrificial stack portions; removing the sacrificial stack portions to form a plurality of trenches such that two adjacent ones of the metal line structures are spaced apart from each other by a corresponding one of the trenches; conformally forming an etch stop layer to cover the metal line structures; and forming a dielectric layer to cover the etch stop layer, the dielectric layer including a lower dielectric layer portion and an upper dielectric layer portion disposed on and in direct contact with the lower dielectric layer portion.

In accordance with some embodiments of the present disclosure, the method for manufacturing a semiconductor device further includes before formation of the sacrificial stack portions, forming a via layer on the semiconductor substrate, the via layer including a via structure exposing from a trench formed between two corresponding ones of the sacrificial stack portions; and after formation of the sacrificial stack portions and before formation of the etch stop layer, selectively forming a dielectric cap layer on the via structure, conformally forming an oxidation prevention layer on the sacrificial stack portions to laterally cover the metal line structures and to expose the cap layer, and removing the cap layer to expose the via structure to be connected to a corresponding one of the metal line structures, the oxidation prevention layer being disposed between the metal line structures and the etch stop layer.

In accordance with some embodiments of the present disclosure, the method for manufacturing a semiconductor device further includes before conformal formation of the etch stop layer, forming a conductive cap layer on the metal line structures such that the conductive cap layer is disposed between the etch stop layer and the metal line structures.

In accordance with some embodiments of the present disclosure, each of the trenches having a width decreasing gradually in a direction from a lower surface to an upper surface of each of the metal line structures. An upper end of each of the trenches has a width less than 35 nm. The dielectric layer is formed by physical vapor deposition or chemical vapor deposition using a low-k dielectric material including silicon oxide, silicon oxycarbide, or a combination thereof, such that a plurality of air gaps are formed among the metal line structures.

In accordance with some embodiments of the present disclosure, the metal line structures are formed in the lower dielectric layer portion of the dielectric layer. the method for manufacturing a semiconductor device further includes forming a plurality of interconnect structures in the upper dielectric layer portion of the dielectric layer, such that at least one of the interconnect structures is respectively connected to at least one of the metal line structures.

In accordance with some embodiments of the present disclosure, a semiconductor device includes a semiconductor substrate, a dielectric layer, a plurality of metal line structures, and at least one interconnect structure. The dielectric layer is disposed on the semiconductor substrate, and includes a lower dielectric layer portion and an upper dielectric layer portion disposed on the lower dielectric layer portion opposite to the semiconductor substrate and in direct contact with the lower dielectric layer portion. The metal line structures are disposed in the lower dielectric layer portion of the dielectric layer and spaced apart from each other. The at least one interconnect structure is disposed in the upper dielectric layer portion and respectively connected to at least one of the metal line structures.

In accordance with some embodiments of the present disclosure, each of the metal line structures includes a bulk metal portion and a self-forming etch stop portion disposed on the bulk metal portion. The bulk metal portion includes a first metal and a second metal different from the first metal. The first metal has a reduction potential lower than that of the second metal. The self-forming etch stop portion includes a metal oxide of the first metal.

In accordance with some embodiments of the present disclosure, each of the metal line structures further includes a self-forming barrier laterally covering the bulk metal portion and the self-forming etch stop portion and covering a bottom surface of the bulk metal portion. The self-forming barrier includes a metal oxide, a metal silicide, or a combination thereof of the first metal.

In accordance with some embodiments of the present disclosure, the semiconductor device further includes a conductive cap layer including a plurality of conductive cap portions disposed on the metal line structures, respectively.

In accordance with some embodiments of the present disclosure, the semiconductor device further includes an etch stop layer laterally covering the metal line structures and the conductive cap portions.

In accordance with some embodiments of the present disclosure, each of the metal line structures has a width gradually decreasing in a direction from an upper surface to a lower surface of the each of the metal line structures, such that a plurality of air gaps are formed in the lower dielectric layer portion and among the metal line structures.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a plurality of sacrificial stack portions on a semiconductor substrate, the sacrificial stack portions being spaced apart from each other;
forming a metal material layer to cover the sacrificial stack portions, the metal material layer including a first metal and a second metal different from the first metal, the first metal having a reduction potential lower than that of the second metal; and
annealing the metal material layer to form a self-forming barrier layer conformally covering the sacrificial stack portions, the self-forming barrier layer including a metal oxide, a metal silicide, or a combination thereof formed from the first metal by annealing.

2. The method as claimed in claim 1, wherein:
each of the sacrificial stack portions includes a sacrificial metal portion and a hard mask portion disposed on the sacrificial metal portion opposite to the semiconductor substrate;
the method further comprises removing the hard mask portions of the sacrificial stack portions by a planarization process to expose the sacrificial metal portions of the sacrificial stack portions and to form a plurality of metal line structures spaced apart from each other by the sacrificial metal portions; and
each of the metal line structures includes a bulk metal portion, a self-forming etch stop portion disposed on the bulk metal portion, and a self-forming barrier formed from the self-forming barrier layer to laterally cover the bulk metal portion and the self-forming etch stop portion and to cover a bottom surface of the bulk metal portion, the self-forming etch stop portion including a metal oxide formed by oxidation of the first metal in the planarization process.

3. The method as claimed in claim 2, further comprising:
before formation of the sacrificial stack portions, forming a via layer on the semiconductor substrate, the via layer including a via structure exposing from a first trench formed between two corresponding ones of the sacrificial stack portions; and
after formation of the sacrificial stack portions, selectively forming a cap layer on the via structure, conformally forming an oxidation prevention layer on the sacrificial stack portions such that the cap layer is exposed, and removing the cap layer to expose the via structure to be connected to a corresponding one of the metal line structures.

4. The method as claimed in claim 3, further comprising:
removing the sacrificial metal portions to form a plurality of second trenches among the metal line structures, each of the second trenches having a width decreasing gradually in a direction from a lower surface to an upper surface of each of the metal line structures; and
forming a dielectric layer to cover the metal line structures, the dielectric layer including a lower dielectric layer portion and an upper dielectric layer portion disposed on and in direct contact with the lower dielectric layer portion.

5. The method as claimed in claim 4, wherein:
an upper end of each of the second trenches has a width less than 35 nm; and
the dielectric layer is formed by physical vapor deposition or chemical vapor deposition using a low-k dielectric material including silicon oxide, silicon oxycarbide, or a combination thereof, such that a plurality of air gaps are formed among the metal line structures.

6. The method as claimed in claim 3, wherein:
the first metal proximate to the oxidation prevention layer is subjected to oxidation, siliconization, or a combination thereof in annealing the metal material layer, such that the self-forming barrier layer is conformally formed on the oxidation prevention layer.

7. The method as claimed in claim 2, wherein the planarization process is performed by a buffing chemical mechanical planarization using a slurry including an oxidant, such that the oxidation of the first metal in the planarization process is performed by the oxidant.

8. The method as claimed in claim 1, wherein the metal material layer includes an alloy represented by AₓB_{y}, wherein x is an integer ranging from 1 to 5, y is an integer ranging from 1 to 10, A represents the first metal including one of aluminum, chromium, manganese, zirconium, niobium, and combinations thereof, and B represents the second metal including one of ruthenium, copper, cobalt, and combinations thereof.

9. The method as claimed in claim 4, wherein:
the metal line structures are formed in the lower dielectric layer portion of the dielectric layer;
the method further comprises forming a plurality of interconnect structures in the upper dielectric layer portion of the dielectric layer, such that at least one of the interconnect structures is respectively connected to at least one of the metal line structures.

10. A method for manufacturing a semiconductor device, comprising:
forming a plurality of sacrificial stack portions on a semiconductor substrate, the sacrificial stack portions being spaced apart from each other;
forming a plurality of metal line structures among the sacrificial stack portions such that two adjacent ones of the metal line structures are spaced apart from each other by a corresponding one of the sacrificial stack portions;
removing the sacrificial stack portions to form a plurality of trenches such that two adjacent ones of the metal line structures are spaced apart from each other by a corresponding one of the trenches;
conformally forming an etch stop layer to cover the metal line structures; and
forming a dielectric layer to cover the etch stop layer, the dielectric layer including a lower dielectric layer portion and an upper dielectric layer portion disposed on and in direct contact with the lower dielectric layer portion.

11. The method as claimed in claim 10, further comprising:
before formation of the sacrificial stack portions, forming a via layer on the semiconductor substrate, the via layer including a via structure exposing from a trench formed between two corresponding ones of the sacrificial stack portions; and
after formation of the sacrificial stack portions and before formation of the etch stop layer, selectively forming a dielectric cap layer on the via structure, conformally forming an oxidation prevention layer on the sacrificial stack portions to laterally cover the metal line structures and to expose the cap layer, and removing the cap layer to expose the via structure to be connected to a corresponding one of the metal line structures, the oxidation prevention layer being disposed between the metal line structures and the etch stop layer.

12. The method as claimed in claim 10, further comprising, before conformal formation of the etch stop layer, forming a conductive cap layer on the metal line structures such that the conductive cap layer is disposed between the etch stop layer and the metal line structures.

13. The method as claimed in claim 10, wherein:
each of the trenches having a width decreasing gradually in a direction from a lower surface to an upper surface of each of the metal line structures;
an upper end of each of the trenches has a width less than 35 nm; and
the dielectric layer is formed by physical vapor deposition or chemical vapor deposition using a low-k dielectric material including silicon oxide, silicon oxycarbide, or a combination thereof, such that a plurality of air gaps are formed among the metal line structures.

14. The method as claimed in claim 10, wherein:
the metal line structures are formed in the lower dielectric layer portion of the dielectric layer;
the method further comprises forming a plurality of interconnect structures in the upper dielectric layer portion of the dielectric layer, such that at least one of the interconnect structures is respectively connected to at least one of the metal line structures.

15. A semiconductor device, comprising:
a semiconductor substrate;
a dielectric layer disposed on the semiconductor substrate, the dielectric layer including a lower dielectric layer portion and an upper dielectric layer portion disposed on the lower dielectric layer portion opposite to the semiconductor substrate and in direct contact with the lower dielectric layer portion;
a plurality of metal line structures disposed in the lower dielectric layer portion of the dielectric layer and spaced apart from each other; and
at least one interconnect structure disposed in the upper dielectric layer portion and respectively connected to at least one of the metal line structures.

16. The semiconductor device as claimed in claim 15, wherein:
each of the metal line structures includes a bulk metal portion and a self-forming etch stop portion disposed on the bulk metal portion, wherein:
the bulk metal portion includes a first metal and a second metal different from the first metal, the first metal having a reduction potential lower than that of the second metal, and
the self-forming etch stop portion includes a metal oxide of the first metal.

17. The semiconductor device as claimed in claim 16, wherein each of the metal line structures further includes a self-forming barrier laterally covering the bulk metal portion and the self-forming etch stop portion and covering a bottom surface of the bulk metal portion, the self-forming barrier including a metal oxide, a metal silicide, or a combination thereof of the first metal.

18. The semiconductor device as claimed in claim 15, further comprising a conductive cap layer including a plurality of conductive cap portions disposed on the metal line structures, respectively.

19. The semiconductor device as claimed in claim 18, further comprising an etch stop layer laterally covering the metal line structures and the conductive cap portions.

20. The semiconductor device as claimed in claim 15, wherein each of the metal line structures has a width gradually decreasing in a direction from an upper surface to a lower surface of the each of the metal line structures, such that a plurality of air gaps are formed in the lower dielectric layer portion and among the metal line structures.
